(19) United States
(12) Patent Application Publication
(10) Pub. No.: US 2025/0338563 A1
(43) Pub. Date: Oct. 30, 2025

(54) LAMINATE STRUCTURE AND THIN FILM TRANSISTOR

(71) Applicant: IDEMITSU KOSAN CO.,LTD., Tokyo (JP)

(72) Inventors: Yuki TSURUMA, Chiyoda-ku, Tokyo (JP); Emi KAWASHIMA, Chiyoda-ku, Tokyo (JP); Nobuhiro IWASE, Chiyoda-ku, Tokyo (JP); Koji YAMAGUCHI, Chiyoda-ku,Tokyo (JP); Hiroyuki MIWA, Chiyoda-ku, Tokyo (JP)

(73) Assignee: IDEMITSU KOSAN CO.,LTD., Tokyo (JP)

(21) Appl. No.: 18/870,303

(22) PCT Filed: May 25, 2023
(86) PCT No.: PCT/JP2023/019465

§ 371 Date: Nov. 27, 2024

(30) Foreign Application Priority Data
May 31, 2022 (JP) 2022-089282

(51) Int. Cl. H10D 30/67; H10D 30/01; H10D 62/40; H10D 62/60; H10D 64/68

(52) U.S. Cl. CPC H10D 30/6755; H10D 30/6723; H10D 30/6731; H10D 62/40; H10D 62/60; H10D 64/693; H10D 30/0314

(57) ABSTRACT

Provided is a laminate structure, including: a crystalline oxide semiconductor film containing In as a main component; and an insulating film laminated to form an interface with the crystalline oxide semiconductor film, wherein the laminate structure has a region that satisfies the following formula (1) in the insulating film having a thickness extending from the interface to a distance approximately equal to a thickness of the crystalline oxide semiconductor film:

$$1.25 \leq ( average value of A / B ) \leq 1.75 \qquad ( 1 )$$

where A represents the number of oxygen atoms, and B represents the number of cation atoms that exist in a state of being bonded to the oxygen atoms, the cation atoms being cationic atomic species contained in the laminate structure in an amount of 1 at % or more.

### TECHNICAL FIELD

The present disclosure relates to a laminate structure and a thin film transistor.

### BACKGROUND ART

A thin film transistor (TFT) using an amorphous oxide semiconductor for a channel layer has been widely known (see Patent Document 1). However, the TFT has a low mobility, and hence there is a demand for improvement.

As a TFT that can obtain a high mobility characteristic as compared to the TFT using an amorphous oxide semiconductor for a channel layer, a TFT using a crystalline oxide thin film as a channel layer has been known (see, for example, Patent Document 2).

### RELATED ART DOCUMENTS PATENT DOCUMENT

| | |
|---|---|
| [Patent Document 1] | JP 5118810 B2 |
| [Patent Document 2] | WO 2013/035335 A1 |

### SUMMARY OF INVENTION

However, with the technology of Patent Document 2, a threshold voltage (Vth) may fluctuate at the time of use, for example, under an exposure environment, and problems in terms of reliability may occur.

Thus, in the related-art TFT using a crystalline oxide semiconductor film as a channel layer, there is room for improvement in terms of achievement of both the enhancement of the mobility and the reliability of the TFT.

An object of the present disclosure is to provide a laminate structure that exhibits a satisfactory mobility and obtains high reliability when applied to a TFT. In addition, another object of the present disclosure is to provide a thin film transistor having the laminate structure.

According to the present disclosure, the following laminate structure and the like are provided.

1. A laminate structure, including:
a crystalline oxide semiconductor film containing In as a main component; and
an insulating film laminated to form an interface with the crystalline oxide semiconductor film,
wherein the laminate structure has a region that satisfies the following formula (1) in the insulating film having a thickness extending from the interface to a distance approximately equal to a thickness of the crystalline oxide semiconductor film:

$$1.25 \leq ( average value of A / B ) \leq 1.75 \qquad ( 1 )$$

where A represents the number of oxygen atoms, and B represents the number of cation atoms that exist in a state of being bonded to the oxygen atoms, the cation atoms being cationic atomic species contained in the laminate structure in an amount of 1 at % or more.

2. The laminate structure according to Item 1, wherein the laminate structure has a region that satisfies the formula (1) in the crystalline oxide semiconductor film.

3. The laminate structure according to Item 1 or 2, wherein the insulating film is any one of an oxide film containing silicon (Si) as a main component, a nitride film containing silicon (Si) as a main component, and an oxynitride film containing silicon (Si) as a main component.

4. The laminate structure according to any one of Items 1 to 3, wherein the insulating film is an oxide film containing silicon (Si) as a main component.

5. The laminate structure according to any one of Items 1 to 4, wherein the crystalline oxide semiconductor film further contains Ga.

6. The laminate structure according to any one of Items 1 to 5, wherein the crystalline oxide semiconductor film further contains one or more kinds of additive elements selected from B, Al, Si, Sc, Zn, Ge, Y, Zr, Sn, Sm, and Yb.

7. The laminate structure according to any one of Items 1 to 6, wherein an atomic ratio of In with respect to all metal elements contained in the crystalline oxide semiconductor film ([In]/([In]+[all metal elements except In])×100) is 62 at % or more.

8. The laminate structure according to any one of Items 5 to 7, wherein an atomic ratio of Ga with respect to all metal elements contained in the crystalline oxide semiconductor film ([Ga]/([Ga]+[all metal elements except Ga])×100) is 30 at % or less.

9. The laminate structure according to any one of Items 6 to 8, wherein an atomic ratio of a total amount of the additive elements with respect to all metal elements contained in the crystalline oxide semiconductor film ([total amount of additive elements]/([total amount of additive elements]+[all metal elements except additive elements])×100) is 10 at % or less.

10. The laminate structure according to any one of Items 1 to 9, wherein the crystalline oxide semiconductor film has a carrier concentration of 1×10¹⁸ cm⁻³ or less.

11. The laminate structure according to any one of Items 1 to 10, wherein the crystalline oxide semiconductor film contains a crystal grain having a bixbyite structure.

12. A thin film transistor, including the laminate structure of any one of Items 1 to 11, wherein the thin film transistor includes:
a channel layer;
a source electrode and a drain electrode each connected to the channel layer; and
a gate electrode laminated on the channel layer through intermediation of a gate insulating film,
wherein the channel layer is the crystalline oxide semiconductor film, and
wherein the gate insulating film is the insulating film.

13. The thin film transistor according to Item 12, wherein the thin film transistor is a top-gate type transistor.

14. A semiconductor element, including the laminate structure of any one of Items 1 to 11.

15. A diode, a thin film transistor, a MOSFET, or a MESFET, including the semiconductor element of Item 14.

16. An electronic circuit, including the diode, the thin film transistor, the MOSFET, orthe MESFET of Item 15.

17. An electric device, an electronic device, a vehicle, or a power engine, including the electronic circuit of Item 16.

According to the present disclosure, the laminate structure that exhibits a satisfactory mobility and obtains high reliability when applied to a TFT can be provided. In addition, the thin film transistor having the laminate structure can be provided.

### BRIEF DESCRIPTION OF DRAWINGS

FIG. 1 is a schematic sectional view of an example of a laminate structure of an aspect of the present disclosure.

FIG. 2 shows a TEM image in which the vicinity of an interface between a crystalline oxide semiconductor film and an insulating film is enlarged.

FIG. 3 is a schematic sectional view of an example of a TFT of this aspect.

FIG. 4 is a schematic sectional view of another example of the TFT of this aspect.

FIG. 5 is a schematic sectional view of another example of the TFT of this aspect.

FIG. 6 is a schematic sectional view of a TFT produced in Example.

FIG. 7 shows EDX spectra obtained by EDX line analysis of the laminate structures obtained in Example 1 and Comparative Example 1.

### DESCRIPTION OF EMBODIMENTS

The ordinal numbers “first,” “second,” and “third” as used herein are attached for avoiding confusion between constituents. Constituents without descriptions that specify the order are not limited to the numerical order of the ordinal numbers.

As used herein, the term “film” or “thin film” and the term “layer” are sometimes interchangeable with each other.

In a sintered body and an oxide thin film as used herein, the term “compound” and the term “crystal phase” are sometimes interchangeable with each other.

As used herein, the term “oxide sintered body” is sometimes simply referred to as “sintered body.”

As used herein, the term “sputtering target” is sometimes simply referred to as “target.”

As used herein, the term “electrically connected” encompasses connection through an “object of some electric action.” The “object of some electric action” is not particularly limited as long as the object allows communication of electric signals between connected components. Examples of the “object of some electric action” include an electrode, a line, a switching element (e.g., a transistor), a resistive element, an inductor, a capacitor, and other elements having various functions.

As used herein, the functions of the source and drain of a transistor may be interchanged when, for example, a transistor of different polarity is adopted or the direction of a current is changed during the operation of a circuit. Accordingly, the terms “source” and “drain” as used herein may be interchangeably used.

As used herein, the term “x to y” refers to a numerical range of “x or more and y or less.” An upper limit value and a lower limit value described regarding the numerical range may be arbitrarily combined.

In addition, the present disclosure also encompasses modes obtained by combining two or more individual modes of the present disclosure described below.

### 1. Laminate Structure

A laminate structure according to an aspect of the present disclosure includes a crystalline oxide semiconductor film containing In as a main component, and an insulating film laminated to form an interface with the crystalline oxide semiconductor film.

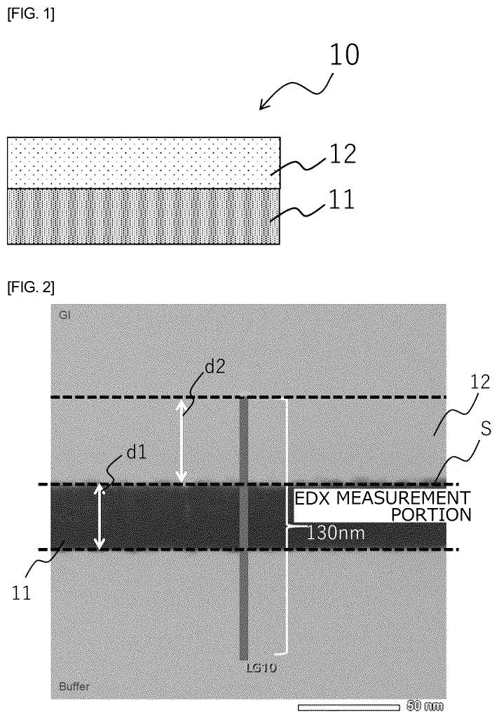

FIG. 1 is a schematic sectional view of an example of a laminate structure of an aspect of the present disclosure.

A laminate structure 10 includes a crystalline oxide semiconductor film 11, and an insulating film 12 laminated to form an interface with the crystalline oxide semiconductor film 11.

FIG. 2 shows a TEM image in which the vicinity of the interface between the crystalline oxide semiconductor film 11 and the insulating film 12 is enlarged.

In FIG. 2, S denotes the interface between the crystalline oxide semiconductor film 11 and the insulating film 12, and d1 denotes the thickness of the crystalline oxide semiconductor film 11. The insulating film 12 has a region that satisfies the following formula (1) in a film having a thickness (at a position indicated by the broken lines in FIG. 2) extending from the interface S to a distance d2 approximately equal to the thickness d1 of the crystalline oxide semiconductor film 11. The term “distance approximately equal” refers to a distance of (equal distance)±5%, preferably ±3%, more preferably ±1%.

$$1.25 \leq ( average value of A / B ) \leq 1.75 \qquad ( 1 )$$

In the formula (1), A represents the number of oxygen atoms, and B represents the number of cation atoms that exist in a state of being bonded to the oxygen atoms.

The cation atoms are cationic atomic species contained in the laminate structure in an amount of 1 at % or more.

Typical examples of the cation atoms that exist in a state of being bonded to the oxygen atoms include In, Ga, Si, B, Mg, Al, Ca, Sc, Ti, V, Cr, Mn, Fe, Co, Ni, Cu, Zn, Ge, Sr, Y, Zr, Nb, Mo, Ru, Rh, Pd, Ag, Cd, Sn, Ba, La, Ce, Pr, Nd, Sm, Eu, Gd, Tb, Dy, Ho, Er, Tm, Yb, Lu, Hf, Ta, and W.

In each of the films, the number of oxygen atoms A and the number of cation atoms B that exist in a state of being bonded to the oxygen atoms may be measured by energy dispersive X-ray analysis (EDX analysis). A method of measuring the number of atoms A and the number of atoms B by the EDX analysis is described in detail in Examples.

The expression “average value of A/B” in the formula (1) means that the number of oxygen atoms A and the number of cation atoms B may each vary in each thickness site of the crystalline oxide semiconductor film or the insulating film.

When the insulating film 12 has a region that satisfies the formula (1) in the thickness from the interface S to the distance d2, the stability of the insulating film 12 and the crystalline oxide semiconductor film 11 in contact therewith is increased. Thus, when a laminate structure including those films is applied to a TFT, a threshold voltage (Vth) less fluctuates, and excellent reliability is obtained.

Although the reason for such effect is not entirely clear, it is inferred that the effect is obtained by the fact that the insulating film having a region that satisfies the formula (1) suppresses the phenomenon in which holes generated in the crystalline oxide semiconductor film 11 migrate to the insulating film to cause the characteristics of the insulating film to deteriorate when the TFT is driven under a high-voltage stress environment, for example, under an exposure environment.

The average value of A/B in the insulating film may be 1.25 or more, 1.4 or more, 1.45 or more, 1.48 or more, or 1.5 or more, and may be 1.75 or less, 1.7 or less, 1.64 or less, or 1.6 or less.

The average value of A/B in the insulating film is preferably from 1.25 to 1.75, more preferably from 1.4 to 1.75, still more preferably from 1.45 to 1.64, yet still more preferably from 1.48 to 1.6, even yet still more preferably from 1.5 to 1.6.

In one embodiment, the laminate structure has a region that satisfies the formula (1) in the crystalline oxide semiconductor film 11.

With this configuration, the stability of the insulating film 12 and the crystalline oxide semiconductor film 11 in contact therewith is further increased. Thus, when a laminate structure including those films is applied to a TFT, the threshold voltage (Vth) less fluctuates, and excellent reliability is obtained.

The average value of A/B in the crystalline oxide semiconductor film may be 1.25 or more, 1.4 or more, 1.45 or more, 1.48 or more, or 1.5 or more, and may be 1.78 or less, 1.75 or less, 1.6 or less, 1.56 or less, or 1.55 or less.

The average value of A/B in the crystalline oxide semiconductor film is preferably from 1.25 to 1.75, more preferably from 1.4 to 1.6, still more preferably from 1.45 to 1.56, yet still more preferably from 1.45 to 1.55.

The region that satisfies the formula (1) in the insulating film may be formed by performing surface treatment at the timing after the formation of the crystalline oxide semiconductor film and/or at the timing during or after the formation of the insulating film to suppress oxygen diffusion in each of the films. A specific method for the surface treatment is described in detail in “Method of producing Laminate Structure.”

### (Crystalline Oxide Semiconductor Film)

The crystalline oxide semiconductor film 11 in this aspect (hereinafter simply referred to as “crystalline oxide semiconductor film”) contains an In element as a main component. The In element being a main component means that the atomic ratio of In with respect to all metal elements in the crystalline oxide semiconductor film ([In]/([In]+[all metal elements except In])×100) (atomic %: at %) is 50 at % or more. The atomic ratio of In is preferably 62 at % or more, more preferably 70 at % or more, still more preferably 80 at % or more, yet still more preferably 84 at % or more, even yet still more preferably 85 at % or more. When the In element accounts for 50 at % or more of the total number of atoms of metal elements for forming the crystalline oxide semiconductor film, a sufficiently high mobility can be exhibited when the laminate structure according to this aspect is adopted in a TFT.

The crystalline oxide semiconductor film may be formed of a single crystalline oxide semiconductor or a polycrystalline oxide semiconductor. However, it is difficult to form a uniform single crystal on a substrate having a large area in many cases, and hence it is preferred that the crystalline oxide semiconductor film be formed of a polycrystalline oxide semiconductor.

In one embodiment, the crystalline oxide semiconductor film may contain Ga in addition to In.

When the crystalline oxide semiconductor film contains Ga, the atomic ratio of Ga with respect to all metal elements in the crystalline oxide semiconductor film ([Ga]/([Ga]+[all metal elements except Ga])×100) (atomic %: at %) is preferably 30 at % or less, more preferably 20 at % or less, still more preferably 16 at % or less, yet still more preferably 15 at % or less.

When the Ga element accounts for 30 at % or less of the total number of atoms of metal elements for forming the crystalline oxide semiconductor film, a sufficiently high mobility can be exhibited when the laminate structure according to this embodiment is adopted in a TFT.

The crystalline oxide semiconductor film may contain, in addition to In, one or more elements selected from the group consisting of: H; B; C; N; O; F; Mg; Al; Si; O; S; Cl; Ar; Ca; Sc; Ti; V; Cr; Mn; Fe; Co; Ni; Cu; Zn; Ga; Ge; Y; Zr; Nb; Mo; Tc; Ru; Rh; Pd; Ag; Cd; Sn; Sb; Cs; Ba; Ln; Hf; Ta; W; Re; Os; Ir; Pt; Au; Pb; and Bi.

In one embodiment, the crystalline oxide semiconductor film may contain, in addition to In, one or more kinds of additive elements Z selected from B, Al, Si, Sc, Zn, Ge, Y, Zr, Sn, Sm, and Yb.

When the crystalline oxide semiconductor film contains the additive element Z, the atomic ratio of the total amount of the additive element Z with respect to all metal elements in the crystalline oxide semiconductor film ([total amount of additive element Z]/([total amount of additive element Z]+[all metal elements except additive element Z])×100) (atomic %: at %) is preferably 10 at % or less, more preferably 7.5 at % or less, still more preferably 5 at % or less.

When the total amount of the additive element Z is 10 at % or less of the total number of atoms of metal elements for forming the crystalline oxide semiconductor film, a sufficiently high mobility can be exhibited when the laminate structure according to this embodiment is adopted in a TFT.

In this embodiment, the crystalline oxide semiconductor film may consist essentially of elements selected from In, Mg, Al, Si, Zn, Ga, Mo, Sn, lanthanoid elements (Ln elements), and O. As used herein, the term “essentially” means that the crystalline oxide semiconductor film of the laminate structure according to this embodiment may contain any other component to the extent that the effects of the present disclosure attributed to the combination of In, Mg, Al, Si, Zn, Ga, Mo, Sn, Ln, and O described above are exhibited.

In the crystalline oxide semiconductor film according to a more preferred first mode of this embodiment, the metal elements consist of In and Ga, and the atomic ratios satisfy the following formula (11).

$$[ Ga ] / ( [ ln ] + [ Ga ] ) < 22 at \% \qquad ( 11 )$$

The crystalline oxide semiconductor film may contain inevitable impurities as the metal elements, and further F or H in addition to O. When the above-mentioned composition range is satisfied, the In ratio is increased, and crystallization to a bixbyite structure in which an In site is substituted by Ga can be achieved even by annealing at a low temperature such as 300° C. Further, when Ga having a strong bonding force with oxygen is added, oxygen deficiency after annealing is suppressed, and a film that is stable as a semiconductor can be formed.

The crystalline oxide semiconductor film according to a more preferred second mode of this embodiment consists of In, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as the metal elements, and when the metal element except In is represented by X, the atomic ratios satisfy the following formula (12).

$$[ X ] / ( [ ln ] + [ X ] ) < 15 at \% \qquad ( 12 )$$

The crystalline oxide semiconductor film may contain inevitable impurities as the metal elements, and further F or H in addition to O. When the above-mentioned composition range is satisfied, the In ratio is increased, and crystallization to a bixbyite structure in which an In site is substituted by X can be achieved even by annealing at a low temperature such as 300° C. Further, when the element X having a strong bonding force with oxygen is added, oxygen deficiency after annealing is suppressed, and a film that is stable as a semiconductor can be formed.

The crystalline oxide semiconductor film according to a more preferred third mode of this embodiment consists of In, Ga, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as the metal elements, and when the metal element except In and Ga is defined as an additive element X, the atomic ratios satisfy the following formulae (13) and (14).

$$[ Ga ] / ( [ ln ] + [ Ga ] + [ X ] ) < 22.5 at \% \qquad ( 13 )$$

$$[ X ] / ( [ ln ] + [ Ga ] + [ X ] ) < 8. at \% \qquad ( 14 )$$

The crystalline oxide semiconductor film may contain inevitable impurities as the metal elements, and further F or H in addition to O.

When the above-mentioned composition range is satisfied, the In ratio is increased, and crystallization to a bixbyite structure in which an In site is substituted by Ga can be achieved even by annealing at a low temperature such as 300° C. In addition, when the additive element X having a strong bonding force with oxygen is added, oxygen deficiency after annealing is further suppressed, and a film that is stable as a semiconductor can be formed.

The crystalline oxide semiconductor film according to a more preferred fourth mode of this embodiment consists of In, Sn, and one or more elements X selected from B, Al, Sc, Mg, Zn, Ti, Y, Zr, Mo, Hf, W, Nb, Ta, Ge, Si, La, Ce, Pr, Nd, Sm, Dy, Ho, Er, Tm, Yb, and Lu as the metal elements, and when the metal element except In and Sn is defined as an element X, the atomic ratios satisfy the following formulae (15) and (16).

$$[ Sn ] / ( [ ln ] + [ Sn ] + [ X ] ) < 20 at \% \qquad ( 15 )$$

$$[ X ] / ( [ ln ] + [ Sn ] + [ X ] ) < 8. at \% \qquad ( 16 )$$

The crystalline oxide semiconductor film may contain inevitable impurities as the metal elements, and further F or H in addition to O.

When the composition range as described above is satisfied, the In ratio is increased, and crystallization to a bixbyite structure in which an In site is substituted by Sn can be achieved even by annealing at a low temperature such as 300° C. Sn has a large ion radius and a large orbital overlap with In, and hence a high mobility can be held. In addition, when the additive element X having a strong bonding force with oxygen is added, oxygen deficiency after annealing is further suppressed, and a film that is stable as a semiconductor can be formed.

The crystalline oxide semiconductor film according to a more preferred fifth mode of this embodiment consists of In, Zn, and one or more elements X selected from B, Al, Sc, Mg, Ti, Y, Zr, Mo, Hf, W, Nb, Ta, Ge, Si, La, Ce, Pr, Nd, Sm, Dy, Ho, Er, Tm, Yb, and Lu as the metal elements, and when the metal element except In and Zn is defined as an element X, the atomic ratios satisfy the following formulae (17) and (18).

$$[ Zn ] / ( [ ln ] + [ Zn ] + [ X ] ) < 12 at \% \qquad ( 17 )$$

$$[ X ] / ( [ ln ] + [ Zn ] + [ X ] ) < 8. at \% \qquad ( 18 )$$

The crystalline oxide semiconductor film may contain inevitable impurities as the metal elements, and further F or H in addition to O.

When the above-mentioned composition range is satisfied, the In ratio is increased, and crystallization to a bixbyite structure in which an In site is substituted by Zn can be achieved even by annealing at a low temperature such as 300° C. When Zn is added, the film immediately after film formation can be brought into an amorphous state, and the film can be processed without any residue at the time of semiconductor patterning with an acid during the production of a TFT. Further, when the additive element X having a strong bonding force with oxygen is added, oxygen deficiency after annealing is suppressed, and a film that is stable as a semiconductor can be formed.

The content (atomic ratio) of each metal element in the crystalline oxide semiconductor film may be determined by measuring the abundance of each element by inductively coupled plasma (ICP) measurement or X-ray fluorescence (XRF) measurement. An inductively coupled plasma optical emission spectrometer (ICP-OES manufactured by Agilent) may be used for the ICP measurement. A thin film X-ray fluorescence analyzer (AZX400 manufactured by Rigaku Corporation) may be used for the XRF measurement.

In addition, the content (atomic ratio) of each metal element in the crystalline oxide semiconductor film may be analyzed by TEM-EDS measurement using an electron microscope, ICP measurement using an inductively coupled plasma optical emission spectrometer, and SIMS analysis using a sector-type dynamic secondary ion mass spectrometer.

In one embodiment, the carrier concentration of the crystalline oxide semiconductor film is 1×10¹⁸ cm⁻³ or less, preferably 1×10¹⁷ cm⁻³ or less, more preferably 1×10¹⁶ cm⁻³ or less. With this configuration, the Vth approaches 0 V in an Id-Vg curve when a Vd of 0.1 V is applied to drive a TFT, and satisfactory performance of normally-off characteristics is exhibited.

The carrier concentration is measured by the following method.

The crystalline oxide semiconductor film is cut out into a size of 1 cm square, and an electrode is connected to each of its four corners through use of In solder to provide an element for Hall effect measurement. Then, the carrier concentration is measured. The carrier concentration is determined by performing AC Hall effect measurement through use of Model ResiTest 8400 (manufactured by TOYO Corporation) at room temperature.

Measurement conditions are as described below. The value of the carrier concentration of electrons when an F value as measurement accuracy is 0.9 or more and the absolute value of a Hall voltage phase is from 170° to 180° is adopted.
Current value: 1×10⁻¹² A to 1×10⁻³ A
Magnetic field intensity: 0.36 T

The thickness of the crystalline oxide semiconductor film may be 3 nm or more, 5 nm or more, or 8 nm or more, and may be 100 nm or less, 50 nm or less, 40 nm or less, 31 nm or less, 30 nm or less, or 20 nm or less.

With this configuration, the region that satisfies the formula (1) can be stably formed in the crystalline oxide semiconductor film.

In addition, when the thickness of the crystalline oxide thin film is set to the above-mentioned lower limit value or more, a high-quality crystal can be grown without being influenced by an underlying portion at the time of the crystallization by the annealing (at the time of the formation of the crystalline oxide semiconductor film).

As used herein, the thickness is measured based on a cross-sectional TEM observation image (sometimes referred to as “cross-sectional TEM image”).

In one embodiment, the crystalline oxide semiconductor film contains a crystal grain having a bixbyite structure in its electron beam diffraction. The crystal grain having a bixbyite structure has a cubic crystal shape with satisfactory symmetry, and hence a reduction in TFT characteristic (mobility) can be suppressed even across the crystal grain boundaries.

Whether or not the crystal grain in the crystalline oxide semiconductor film has a bixbyite structure is evaluated by observing the electron beam diffraction pattern of a sample obtained by observing the cross-sectional TEM image.

Specifically, an oxide thin film area observed in the cross-sectional TEM image is irradiated with an electron beam at an irradiation area of about 100 nmφ and an acceleration voltage of 200 kV with a selected area aperture through use of an electron microscope (“Model JEM-2800” manufactured by JEOL Ltd.), and the diffraction pattern is measured with a camera length set to 2 m.

Further, in order to identify the crystal structure, the electron beam diffraction pattern simulation of the bixbyite structure of In₂O₃ is performed with electron beam diffraction simulation software ReciPro (free software ver 4.641 (2019/03/04)). In the simulation, for the crystal structure data of the bixbyite structure, 14388 of Inorganic Crystal Structure Database (ICSD: Japan Association for International Chemical Information) is used, and a space group of la-3, a lattice constant of a=10.17700 Å, and the atomic coordinates of an In site (0.250, 0.250, 0.250), an In site (0.466, 0.000, 0.250), and an O site (0.391, 0.156, 0.380) are used.

Further, the simulation is performed with a camera length of 2 m and 11 kinds of reciprocal lattice vectors (1 0 0), (1 1 1), (1 1 0), (2 1 1), (3 1 1), (2 2 1), (3 3 1), (2 1 0), (3 1 0), (3 2 1), and (2 3 0) as incident electron beam directions.

The results of the diffraction points of the electron beam diffraction pattern of the oxide thin film are compared to those of the resultant simulation pattern. When the result has matched any one of the 11 kinds of simulation patterns, it is judged that the oxide thin film contains a crystal grain having a bixbyite structure.

It is desired that the crystalline oxide semiconductor film contain a crystal grain having a Bixbyite structure. However, when an electron beam diffraction pattern can be recognized in an oxide thin film area observed with an electron microscope as described above, the oxide thin film may be regarded as a crystalline oxide semiconductor film.

### (Insulating Film)

A material for forming the insulating film is not particularly limited, and any material that is generally used may be selected. In addition, a laminated film may be used. For example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN may be used. The oxidation numbers of the respective materials may be varied.

In one embodiment, the insulating film is any one of an oxide film containing silicon (Si) as a main component, a nitride film containing silicon (Si) as a main component, and an oxynitride film containing silicon (Si) as a main component.

With this configuration, the ratios of the cation atoms and the oxygen atoms in the insulating film and in the crystalline oxide semiconductor film are easily controlled appropriately through a surface treatment step performed in the method of producing a laminate structure described later, and the region that satisfies the formula (1) is stably obtained.

From the viewpoints of ease of availability and stability of the insulating film, the insulating film is more preferably an oxide film containing silicon (Si) as a main component.

The oxide film containing silicon (Si) as a main component means an oxide film in which the atomic ratio of silicon (Si) with respect to all cation atoms contained in the oxide film is 90 at % or more, the nitride film containing silicon (Si) as a main component means a nitride film in which the atomic ratio of silicon (Si) with respect to all cation atoms contained in the nitride film is 90 at % or more, and the oxynitride film containing silicon (Si) as a main component means an oxynitride film in which the atomic ratio of silicon (Si) with respect to all cation atoms contained in the oxynitride film is 90 at % or more.

The thickness of the insulating film may be 50 nm or more, 98 nm or more, 100 nm or more, or 150 nm or more, and may be 500 nm or less, 300 nm or less, or 200 nm or less.

With this configuration, the region that satisfies the formula (1) can be stably formed in the insulating film or in the insulating film and the crystalline oxide semiconductor film.

In addition, when the thickness of the crystalline oxide semiconductor film is set to an upper limit value or less, a stable element shape is obtained when the laminate structure of this embodiment is applied to a TFT.

The insulating film 12 may be a single layer film or a laminated film. In the case of the laminated film, the suitable thickness described regarding the insulating film 12 is the thickness of the entire laminated film. When a film is obtained in the surface treatment step in the method of producing a laminate structure described later, the film is integrated with the insulating film 12 to function as a gate insulating film 24 of a TFT in the form of a laminated film.

### 2. Method of Producing Laminate Structure

The laminate structure of this aspect may be produced, for example, by forming an oxide thin film containing an oxide of In as a main component on a lower layer or the like for forming a TFT, such as a substrate, a buffer layer, or an insulating layer, and subjecting the oxide thin film to crystallization treatment to form a crystalline oxide semiconductor film (crystalline oxide semiconductor film formation step), and then forming an insulating film in contact with the crystalline oxide semiconductor film (insulating film formation step). When the surface treatment is performed between the formation of the crystalline oxide semiconductor film and the formation of the insulating film, and/or during or after the formation of the insulating film, the region that satisfies the formula (1) can be formed in the insulating film and/or the crystalline oxide semiconductor film.

A method of forming an oxide thin film containing an oxide of In as a main component is not particularly limited, but examples thereof include DC sputtering, AC sputtering, RF sputtering, ICP sputtering, reactive sputtering, ion plating, ALD, PLD, MO-CVD, ICP-CVD, a sol-gel method, a coating method, and mist CVD.

When the film formation is performed by sputtering, the film formation may be performed by a device with a planar sputtering cathode or may be performed by a device with a rotary sputtering cathode.

As an example of the method of forming the oxide thin film, the film may be produced by performing film formation by DC sputtering through use of a sputtering target including an oxide sintered body containing an oxide of In as a main component.

The atomic composition ratio of the oxide thin film obtained by the sputtering method reflects the atomic composition ratio of the oxide sintered body in the sputtering target. Accordingly, the film formation is preferably performed by using a sputtering target including an oxide sintered body having the same atomic composition ratio as the atomic composition ratio of a desired oxide thin film.

In addition, heat treatment may be performed after the formation of the oxide thin film. The step of the heat treatment is not particularly limited, but a hot air furnace, an IR furnace, a lamp annealing device, a laser annealing device, a thermal plasma device, or the like may be used.

Further, plasma oxidation treatment with N₂O or plasma oxidation treatment with O₂ may be performed after the annealing. A device for the plasma oxidation treatment is not particularly limited, but is, for example, PE-CVD.

The content of an impurity metal in the target used in the sputtering method is preferably 500 ppm or less, more preferably 100 ppm or less. The content of the impurity metal in the target may be measured by ICP or SIMS as in the crystalline oxide semiconductor film. The “impurity” contained in the target means a trace element that is mixed in a raw material or during a manufacturing process and is not intentionally added, the element having substantially no influence on the performance of each of the target and the semiconductor. The term “impurity metal” means a metal element among the elements as “impurities.”

In this embodiment, the sputtering target may consist essentially of In and an element selected from Mg, Al, Si, Zn, Ga, Mo, Sn, lanthanoid elements (Ln elements), and O. Herein, the term “essentially” means that the sputtering target may contain any other component in addition to In described above to the extent that the effects of the present disclosure attributed to the combination of Mg, Al, Si, Zn, Ga, Mo, Sn, Ln, and O are exhibited.

As in the crystalline oxide semiconductor film of the laminate structure of the present disclosure described above, the sputtering target according to a more preferred first mode of this embodiment is an oxide consisting of In and Ga as metal elements, and the atomic ratios satisfy the following formula (11).

$$[ Ga ] / ( [ ln ] + [ Ga ] ) < 22 at \% \qquad ( 11 )$$

The sputtering target according to a more preferred second mode is an oxide consisting of In and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as metal elements, and when the metal element except In is represented by X, the atomic ratios satisfy the following formula (12).

$$[ X ] / ( [ ln ] + [ X ] ) < 15 at \% \qquad ( 12 )$$

The sputtering target according to a more preferred third mode is an oxide consisting of In, Ga, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as metal elements, and when the metal element except In and Ga is defined as an additive element X, the atomic ratios satisfy the following formulae (13) and (14).

$$[ Ga ] / ( [ ln ] + [ Ga ] + [ X ] ) < 22.5 at \% \qquad ( 13 )$$

$$[ X ] / ( [ ln ] + [ Ga ] + [ X ] ) < 8. at \% \qquad ( 14 )$$

The sputtering target according to a more preferred fourth mode is an oxide consisting of In, Sn, and one or more elements X selected from B, Al, Sc, Mg, Zn, Ti, Y, Zr, Mo, Hf, W, Nb, Ta, Ge, Si, La, Ce, Pr, Nd, Sm, Dy, Ho, Er, Tm, Yb, and Lu as metal elements, and when the metal element except In and Sn is defined as an element X, the atomic ratios satisfy the following formulae (15) and (16).

$$[ Sn ] / ( [ ln ] + [ Sn ] + [ X ] ) < 20 at \% \qquad ( 15 )$$

$$[ X ] / ( [ ln ] + [ Sn ] + [ X ] ) < 8. at \% \qquad ( 16 )$$

The sputtering target according to a more preferred fifth mode is an oxide consisting of In, Zn, and one or more elements X selected from B, Al, Sc, Mg, Ti, Y, Zr, Mo, Hf, W, Nb, Ta, Ge, Si, La, Ce, Pr, Nd, Sm, Dy, Ho, Er, Tm, Yb, and Lu as metal elements, and when the metal element except In and Zn is defined as an element X, the atomic ratios satisfy the following formulae (17) and (18).

$$[ Zn ] / ( [ ln ] + [ Zn ] + [ X ] ) < 12 at \% \qquad ( 17 )$$

$$[ X ] / ( [ ln ] + [ Zn ] + [ X ] ) < 8. at \% \qquad ( 18 )$$

In the sputtering target according to a preferred mode, the atomic ratio of In with respect to all metal elements contained in the sputtering target ([In]/([In]+[all metal elements except In])×100) is 62 at % or more.

In the sputtering target according to a preferred mode, the atomic ratio of Ga with respect to all metal elements contained in the sputtering target ([Ga]/([Ga]+[all metal elements except Ga])×100) (atomic %: at %) is 30 at % or less.

In the sputtering target according to a preferred mode, the total amount of the additive element Z (one or more kinds selected from B, Al, Si, Sc, Zn, Ge, Y, Zr, Sn, Sm, and Yb) with respect to all metal elements contained in the sputtering target ([total amount of additive element]/([total amount of additive element]+[all metal elements except additive element])×100) (atomic %: at %) is 10 at % or less.

The oxide thin film obtained by film formation by sputtering through use of the sputtering target containing indium oxide as a main component may be an amorphous oxide thin film. The amorphous oxide thin film is patterned into an island shape by photolithography, and is heated to be crystallized before the formation of a protective film. Thus, a crystalline oxide semiconductor film in which a surface crystal has a single crystal orientation can be obtained.

Respective steps are described below with the method of producing a laminate structure illustrated in FIG. 1 being used as an example.

The laminate structure of this embodiment may be produced, for example, by performing a step of forming an oxide thin film containing an oxide of In as a main component on a lower layer or the like for forming a TFT, such as a substrate, a buffer layer, or an insulating layer, and subjecting the oxide thin film to crystallization treatment to form a crystalline oxide semiconductor film (crystalline oxide semiconductor film formation step), and a step of forming an insulating film in contact with the crystalline oxide semiconductor film, followed by heat treatment, to form an insulating film (insulating film formation step).

### [Crystalline Oxide Semiconductor Film Formation Step]

### (Formation of Oxide Thin Film)

In a step of forming an oxide thin film, an oxide thin film is formed by sputtering through use of the above-mentioned sputtering target and through use of, as a sputtering gas, one or more kinds of gases selected from the group consisting of: argon; and oxygen substantially free of impurity gases. In this step, it is preferred that the sputtering be performed by mounting the sputtering target on a RF magnetron sputtering device or a DC magnetron sputtering device.

The sputtering gas being “substantially free of impurity gases” means that impurity gases except the sputtering gas are not actively introduced, except for gases that are brought in by adsorbed water in association with the insertion of gases, and gases that cannot be eliminated (inevitable impurity gases), such as leakage from a chamber and adsorbed gases. Impurities are preferably eliminated from the gas (sputtering gas) to be introduced at the time of the film formation by sputtering, if possible.

The ratio of the impurity gases in the sputtering gas is preferably 0.1 vol % or less, more preferably 0.05 vol % or less. When the ratio of the impurity gases is 0.1 vol % or less, the crystallization of the oxide thin film progresses without any problem.

The purity of each of high-purity argon and high-purity oxygen, which are examples of the sputtering gas, is preferably 99 vol % or more, more preferably 99.9 vol % or more, still more preferably 99.99 vol % or more.

The gas (sputtering gas) to be introduced at the time of the film formation by sputtering is not particularly limited, but examples thereof include argon, nitrogen, oxygen, water, hydrogen, and a mixed gas containing two or more kinds of these gases.

An oxygen partial pressure in a mixed gas in the case of using argon and oxygen as an example is preferably more than 0 vol % and 50 vol % or less, more preferably more than 0 vol % and 20 vol % or less. When the oxygen partial pressure is more than 0 vol % and 50 vol % or less, the oxide thin film is easily crystallized to become a semiconductor at the time of heating. When the oxygen partial pressure is changed, the oxidation degree of the oxide thin film, that is, the crystallization degree thereof can be regulated. It is only required that the oxygen partial pressure be appropriately selected as required.

A water partial pressure in a mixed gas in the case of using argon and water as an example is preferably more than 0.03 vol % and 10 vol % or less, more preferably more than 0.03 vol % and 5 vol % or less. When the water partial pressure is more than 0.03 vol % and 5 vol % or less, the oxide thin film is easily crystallized to become a semiconductor at the time of heating. In addition, a mixed gas of hydrogen and oxygen may be used instead of water.

A crystal can be grown (to a columnar shape with respect to a lower layer, for example) by heating the oxide thin film obtained by sputtering film formation through a heat treatment step described later. When the crystalline oxide semiconductor film formed as described above is applied to a small TFT, the injection property of electron carriers becomes excellent at the time of driving, resulting in a high mobility.

### (Heat Treatment of Oxide Thin Film)

After the formation of the oxide thin film, heat treatment is performed. This heat treatment is sometimes referred to as “annealing.” The annealing treatment of the oxide thin film may be performed before the formation of an insulating film described later or after the formation thereof, but it is preferred to perform the annealing treatment before the formation.

When the annealing is performed before the formation of the insulating film, oxygen and hydrogen are diffused at the time of the annealing, and thus a high-quality columnar crystal is obtained. As a result, a small TFT with a low interfacial electron trap level and a high mobility is obtained after the formation of the insulating film.

The temperature of the heat treatment of the oxide thin film is preferably 250° C. or more and 500° C. or less, more preferably 280° C. or more and 470° C. or less, still more preferably 300° C. or more and 450° C. or less.

When the heat treatment temperature after the formation of the oxide thin film is 250° C. or more, the oxide thin film is easily crystallized. When the heat treatment temperature after the formation of the oxide thin film is 500° C. or less, a crystal can be prevented from abnormally growing to form a large crystal grain, and the crystal grain diameter can be controlled to be small.

A heating time in the step of heat-treating the oxide thin film is preferably 0.1 hour or more and 5 hours or less, more preferably 0.3 hour or more and 3 hours or less, still more preferably 0.5 hour or more and 2 hours or less.

Even when the heating time in the heat treatment step is less than 0.1 hour, the crystallization of the oxide thin film progresses to some extent. However, when the heating time is 0.1 hour or more, atomic diffusion easily progresses in the oxide thin film, and the oxide thin film is easily stabilized after the crystallization. Thus, a stable crystalline oxide semiconductor film is easily obtained. When the heating time in the heat treatment step is 5 hours or less, the heat treatment step is excellent in economic efficiency.

The term “heating time” means a time (retention time) for which a predetermined highest temperature is maintained during the heat treatment.

A rate of temperature increase in the step of heat-treating the oxide thin film is preferably 2° C./min or more and 40° C./min or less, more preferably 3° C./min or more and 20° C./min or less.

When the rate of temperature increase in the step of heat-treating the oxide thin film is 2° C./min or more, the production efficiency of the oxide thin film is increased as compared to a case where the rate of temperature increase is less than 1° C./min.

When the rate of temperature increase in the step of heat-treating the oxide thin film is 40° C./min or less, at the time of the crystallization, the metal elements are uniformly diffused, and crystals in which no metal is segregated at the grain boundaries can be formed.

In addition, the rate of temperature increase in the heat treatment step is different from a value calculated from the set temperature and set time of a furnace, and is a value obtained by dividing the actual temperature of the oxide thin film by a time. The actual temperature of the oxide thin film may be determined, for example, by measuring an area within 1 cm from the oxide thin film in the furnace with a thermocouple.

The step of heat-treating the oxide thin film is preferably performed under an atmospheric atmosphere having a humidity of 10% or more at 25° C. When the heat treatment step is performed in the atmosphere having a humidity of 10% or more, hydrogen and oxygen are diffused into the film at the time of the annealing, and thus the crystallization can be accelerated.

The step of heat-treating the oxide thin film is preferably performed after the patterning of the oxide thin film. When the heat treatment is performed after the patterning, the crystallization of the oxide thin film can be accelerated while excess oxygen existing in the film during the film formation and organic substances adhering during the patterning are desorbed. As a result, a film having no organic substances or excess oxygen and having few crystal defects in the crystal grains can be formed, and an oxide thin film having few electron traps and a satisfactory conduction characteristic can be formed.

Crystal defects in the film after the step of heat-treating the oxide thin film may be evaluated, for example, by defect analysis such as cathodoluminescence (CL). When there are a large number of defects derived from oxygen, a light emission of 680 nm is strongly detected. In order to obtain an oxide thin film having few electron traps and a satisfactory conduction characteristic, it is required to adjust the film formation method and the annealing conditions so as to provide film quality in which the light emission based on the CL is prevented from being detected to the extent possible.

The step of heat-treating the oxide thin film may be performed a plurality of times. For example, the heat treatment step described above (first heat treatment step) may be performed after the patterning of the oxide thin film, and further a heat treatment step (second heat treatment step) may be performed as a final step after the production of a TFT element. The second heat treatment step is preferably performed at an annealing temperature higher than that in the first heat treatment step.

### (Surface Treatment Step)

As a method of forming the region that satisfies the formula (1) in the insulating film, there is given, for example, a method involving subjecting the surface of the crystalline oxide semiconductor film to surface treatment before forming an insulating film and, in some cases, subjecting the insulating film formed by the surface treatment to heat treatment (annealing). The surface treatment and the heat treatment (annealing) of the insulating film described above are sometimes collectively referred to as “surface treatment.”

Through the above-mentioned surface treatment, oxygen diffusion in each of the crystalline oxide semiconductor film and the insulating film can be suppressed, and a laminate structure having the region that satisfies the formula (1) in the insulating film is obtained.

Specifically, when the surface of the crystalline oxide semiconductor film is subjected to the surface treatment, oxygen diffusion in the crystalline oxide semiconductor film and oxygen diffusion from the crystalline oxide semiconductor film to the insulating film side laminated to form an interface with the crystalline oxide semiconductor film can be suppressed, and a laminate structure having the region that satisfies the formula (1) in the insulating film can be formed.

In addition, when a film is formed by the surface treatment, the heat treatment (annealing) of the film further facilitates the suppression of oxygen diffusion in the crystalline oxide semiconductor film and oxygen diffusion from the crystalline oxide semiconductor film to the insulating film side, and a laminate structure having the region that satisfies the formula (1) in the insulating film can be stably produced.

In addition, when the film is formed by the surface treatment, the heat treatment (annealing) of the film can suppress oxygen diffusion in the insulating film and oxygen diffusion to the outside of the insulating film (for example, diffusion to the crystalline oxide semiconductor film side or the film or layer side on a side opposite to the crystalline oxide semiconductor film), and a laminate structure having the region that satisfies the formula (1) in the insulating film can be formed.

Suitable conditions for the heat treatment (annealing treatment) of the insulating film formed by the surface treatment are the same as suitable conditions for the heat treatment of the insulating film described in “Insulating Film Formation Step.”

In addition, when the above-mentioned surface treatment is performed, oxygen diffusion in the crystalline oxide semiconductor film as well as in the insulating film can be suppressed, and a laminate structure having the region that satisfies the formula (1) in the crystalline oxide semiconductor film is obtained.

As a method of forming the region that satisfies the formula (1) in the insulating film, there is typically given a method involving forming a film on the surface of the crystalline oxide semiconductor film by sputtering film formation or chemical vapor deposition (CVD) film formation as the surface treatment and subjecting the formed film to the heat treatment (annealing).

In addition, as another method of forming the region that satisfies the formula (1) in the insulating film, there is given, for example, a method involving subjecting the surface of the crystalline oxide semiconductor film to plasma oxidation treatment with N₂O.

The film to be formed on the surface of the crystalline oxide semiconductor film by the surface treatment is not particularly limited as long as the film does not impair the characteristics of the crystalline oxide semiconductor film, and for example, the same material as that described as the material for forming the insulating film may be used.

From the viewpoints of production efficiency and stability of the laminate, it is preferred to form a film of the same material as that of the insulating film 12.

When the surface treatment is performed through use of the material for forming the insulating film, a laminated film of the film formed by the surface treatment and a film to be formed in the subsequent insulating film formation step may form an insulating film of a TFT.

A method for the surface treatment is not particularly limited, but examples thereof include film formation treatment by a sputtering method, PE-CVD, ALD, PLD, MO-CVD, RF sputtering, ICP sputtering, reactive sputtering, ICP-CVD, ion plating, a sol-gel method, a coating method, and mist CVD.

When the surface treatment is performed by sputtering film formation, the sputtering film formation may be performed by the same method and under the same conditions as those of the formation of the insulating film by sputtering film formation described in “Insulating Film Formation Step.”

When the surface treatment is performed by chemical vapor deposition (CVD) film formation, the temperature at the time of CVD treatment is preferably 240° C. or more and 500° C. or less, more preferably 280° C. or more and 470° C. or less, still more preferably 300° C. or more and 450° C. or less.

When the temperature at the time of CVD treatment falls within the above-mentioned ranges, the region that satisfies the formula (1) can be stably formed in the insulating film.

The temperature at the time of CVD treatment means the temperature of a substrate in a CVD device.

In addition, when the film formation is performed at a temperature of 240° C. or more and 450° C. or less at the time of CVD treatment, the subsequent heat treatment (annealing) step may be omitted.

The thickness of the film formed by the surface treatment may be 1 nm or more and less than 50 nm, from 3 nm to 40 nm, from 4 nm to 35 nm, or from 7 nm to 25 nm.

When the thickness of the film formed by the surface treatment falls within the above-mentioned ranges, the region that satisfies the formula (1) can be stably formed in the insulating film.

A method of forming the region that satisfies the formula (1) in the insulating film or in the insulating film and the crystalline oxide semiconductor film is not limited to the above-mentioned method involving surface treatment (surface treatment of the crystalline oxide semiconductor film and heat treatment of the insulating film), and for example, a method involving subjecting the surface of the crystalline oxide semiconductor film to the plasma oxidation treatment with N₂O (hereinafter sometimes referred to as “N₂O plasma treatment”) may be used.

In the N₂O plasma treatment, specifically, after the surface of the crystalline oxide semiconductor film is subjected to the plasma oxidation treatment with N₂O, an insulating film is formed directly on the plasma treated surface of the crystalline oxide semiconductor film. With this treatment, the oxidation state of a compound or the oxygen bonding state in each of the films in the crystalline oxide semiconductor film and in the insulating film laminated to form an interface with the crystalline oxide semiconductor film can be changed. As a result, for example, oxygen diffusion from the crystalline oxide semiconductor film to the insulating film side and oxygen diffusion from the insulating film to the crystalline oxide semiconductor film side or the other film or layer side can be suppressed, and a laminate structure having the region that satisfies the formula (1) in the insulating film can be formed.

A device for the N₂O plasma treatment is not particularly limited, but PE-CVD or the like may be used.

In the N₂O plasma treatment, for example, it is preferred that a N₂O gas be introduced in a range of from 100 Pa to 10,000 Pa and plasma treatment be performed in a power range of from 5 W to 500 W for from 10 seconds to 1,000 seconds.

When the region that satisfies the formula (1) is formed in the insulating film by the N₂O plasma treatment, it is preferred that the heat treatment (annealing) of the crystalline oxide semiconductor film after the plasma oxidation treatment and before the formation of the insulating film not be performed.

When an insulating film is formed directly on the plasma treated surface of the crystalline oxide semiconductor film under a state in which the crystalline oxide semiconductor film after the plasma oxidation treatment with N₂O is not subjected to the heat treatment (annealing), a laminate structure having the region that satisfies the formula (1) in the insulating film can be stably formed.

When the region that satisfies the formula (1) is formed in the insulating film by the N₂O plasma treatment, the above-mentioned film may not be formed on the crystalline oxide semiconductor film.

In addition, when the region that satisfies the formula (1) is formed in the insulating film by the N₂O plasma treatment, the heat treatment (annealing) of the insulating film is not necessarily required to be performed from the viewpoint of forming the region that satisfies the formula (1) in the insulating film.

### [Insulating Film Formation Step]

The insulating film may be the film formed in the above-mentioned surface treatment step or may be separately formed on the film formed in the above-mentioned surface treatment step. The film formed in the above-mentioned surface treatment step and the insulating film separately formed thereon function as the gate insulating film 24 in a TFT.

### (Formation of Insulating Film)

A method of forming the insulating film is not particularly limited. Examples of the production method include PE-CVD, ALD, PLD, MO-CVD, RF sputtering, ICP sputtering, reactive sputtering, ICP-CVD, ion plating, a sol-gel method, a coating method, and mist CVD. Tetraethoxysilane (TEOS) may be used as the kind of gas in the PE-CVD in addition to silane (SiH₄).

When the insulating film is formed by sputtering, for example, a target containing a silicon (Si)-containing compound (e.g., SiO₂, SiNₓ, or silicon oxynitride) as a main component may be used as a sputtering target. It is preferred that one or more kinds of gases selected from the group consisting of: argon; and oxygen substantially free of impurity gases be used as a sputtering gas in the same manner as in the formation of the oxide thin film described above.

The suitable ranges of the ratio of impurity gases in the sputtering gas and the degree of purity of high-purity argon and high-purity oxygen in the sputtering gas are the same as the suitable ranges in the formation of the oxide thin film described above.

The gas (sputtering gas) to be introduced at the time of the film formation by sputtering is not particularly limited, but examples thereof include argon, nitrogen, oxygen, water, hydrogen, and a mixed gas containing two or more kinds of these gases.

An oxygen partial pressure in a mixed gas in the case of using argon and oxygen as an example is preferably more than 0 vol % and 50 vol % or less, more preferably more than 0 vol % and 40 vol % or less. The atomic ratio of silicon (Si) with respect to all the atoms contained in the insulating film may be adjusted by changing the oxygen partial pressure. It is only required that the oxygen partial pressure be appropriately selected as required.

### (Heat Treatment of Insulating Film)

After the formation of the insulating film, the heat treatment (annealing treatment) is performed. When the heat treatment (annealing treatment) is performed after the formation of the insulating film, the region that satisfies the formula (1) can be stably formed in the insulating film.

In addition, when the heat treatment (annealing treatment) is performed after the formation of the insulating film, hydrogen contained in the insulating film diffuses to the crystalline oxide semiconductor film, and crystal defects that exist on the surface of the crystalline oxide semiconductor film are terminated by a hydroxy group. As a result, a crystalline oxide semiconductor film having few electron traps and a satisfactory conduction characteristic can be formed.

The temperature of the heat treatment after the formation of the insulating film is preferably 250° C. or more and 500° C. or less, more preferably 280° C. or more and 470° C. or less, still more preferably 300° C. or more and 450° C. or less.

When the heat treatment temperature after the formation of the insulating film falls within the above-mentioned ranges, the region that satisfies the formula (1) can be stably formed in the insulating film.

The heating time in the heat treatment step after the formation of the insulating film is preferably 0.1 hour or more and 5 hours or less, more preferably 0.3 hour or more and 3 hours or less, still more preferably 0.5 hour or more and 2 hours or less.

When the heating time in the heat treatment step after the formation of the insulating film is 0.1 hour or more, the region that satisfies the formula (1) can be stably formed in the insulating film.

When the heating time in the heat treatment step after the formation of the insulating film is 5 hours or less, the heat treatment step is excellent in economic efficiency.

The rate of temperature increase in the heat treatment step after the formation of the insulating film is preferably 2° C./min or more and 40° C./min or less, more preferably 3° C./min or more and 20° C./min or less.

When the rate of temperature increase in the heat treatment step after the formation of the insulating film falls within the above-mentioned ranges, the region that satisfies the formula (1) can be stably formed in the insulating film.

A method of determining the rate of temperature increase in the heat treatment step after the formation of the insulating film is the same as the method of determining the rate of temperature increase in the step of heat-treating the oxide film described above.

The heat treatment step after the formation of the insulating film is preferably performed under an atmospheric atmosphere having a humidity of 10% or more at 25° C. When the heat treatment step is performed in the atmosphere having a humidity of 10% or more, the region that satisfies the formula (1) can be stably formed in the insulating film.

The above-mentioned step of forming an insulating film and step of heat-treating the insulating film may be performed only once, or the film formation step and the heat treatment step may be performed a plurality of times. In this case, the thickness of the film formed at the time of each film formation may be the same or different.

### 3. Thin Film Transistor (TFT)

A TFT according to this aspect has the above-mentioned laminate structure of the present disclosure.

In one embodiment, the TFT includes a buffer layer, a channel layer laminated on the buffer layer in contact therewith, a source electrode and a drain electrode each connected to the channel layer, and a gate electrode laminated on the channel layer through intermediation of a gate insulating film. The channel layer is a crystalline oxide semiconductor film included in the laminate structure of the present disclosure, and the gate insulating film is an insulating film included in the laminate structure of the present disclosure.

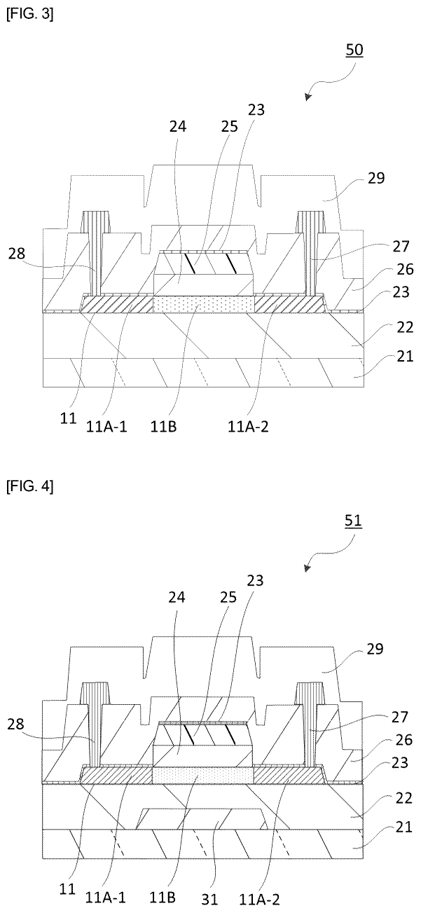

In FIG. 3 and FIG. 4 described later, there is illustrated a configuration in which both end sides of the channel layer, that is, the vicinities of regions to which the source electrode and the drain electrode are connected are low-resistance regions A of the crystalline oxide semiconductor film, and a region in contact with a lower surface of the gate insulating film is a high-resistance region B.

That is, there is illustrated a configuration in which the gate insulating film is formed on the high-resistance region B, and the source electrode and the drain electrode are formed on the low-resistance regions A.

As the configuration of the TFT according to this embodiment, for example, a configuration known in the related art may be adopted.

The TFT according to this aspect may be produced by adopting the method of producing a laminate structure described above. That is, the production method includes: a crystalline oxide semiconductor film formation step including a step of forming an oxide thin film by sputtering through use of a sputtering target and one or more kinds of gases selected from the group consisting of: argon; nitrogen; hydrogen; water; and oxygen substantially free of impurity gases as a sputtering gas (sometimes referred to as “step of forming an oxide thin film”) and a step of subjecting the oxide thin film to heat treatment (sometimes referred to as “step of heat-treating the oxide thin film”); and an insulating film formation step including a step of forming an insulating film on the crystalline oxide semiconductor film by sputtering through use of a sputtering target containing, for example, silicon as a main component (sometimes referred to as “step of forming an insulating film”) and a step of subjecting the insulating film to heat treatment (sometimes referred to as “step of heat-treating the insulating film”). Conditions and the like for each of the film formation steps and each of the heat treatment steps are as described above. A source electrode, a drain electrode, a gate electrode, and a gate insulating film may be formed by known materials and formation methods.

In the laminate structure according to one embodiment, the crystalline oxide semiconductor film has a high mobility and is excellent in stability. When the laminate structure including such crystalline oxide semiconductor film is used as a channel layer of a TFT, a high mobility and high reliability with suppressed threshold voltage (Vth) fluctuations are obtained.

Herein, the mobility at the time of the application of a Vd of 20 V is defined as a saturation mobility. Specifically, a transmission characteristic Id-Vg graph at the time of the application of a Vd of 20 V is created, and a transconductance (Gm) at each Vg is calculated. The calculation may be performed by determining the mobility through use of the formula of a saturation region.

In the following description, the current Id is a current between the source electrode and the drain electrode. The voltage Vd is a voltage (drain voltage) applied between the source electrode and the drain electrode. The voltage Vg is a voltage (gate voltage) applied between the source electrode and the gate electrode.

The shape of the thin film transistor according to this aspect is not particularly limited, but the thin film transistor is preferably a top-gate type transistor, a back channel etch type transistor, an etch stopper type transistor, or the like. In addition, those transistors may be self-aligned transistors.

In one embodiment, it is preferred that the transistors be top-gate type transistors.

Embodiments of the present disclosure are described below with reference to the drawings and the like. It should be easily understood by a person skilled in the art that the embodiments may be carried out in various manners, and their forms and details may be variously modified without departing from the gist and scope of the present disclosure. Accordingly, the present disclosure is not interpreted to be limited to the descriptions in the embodiments below.

In the drawings, a size, a layer thickness, a region, and the like are sometimes exaggerated for clarification. Accordingly, the present disclosure is not limited to the size, the layer thickness, the region, and the like shown in the drawings. The drawings include schematic illustrations of an ideal example, and the present disclosure is not limited to shapes, values, and the like shown in the drawings.

FIG. 3 is a schematic sectional view of an example of the TFT of this aspect.

ATFT 50 is a top-gate type TFT, and includes a substrate 21, a buffer layer 22, a channel layer (crystalline oxide semiconductor film) 11, an ITO layer 23, the gate insulating film (insulating film) 24, a gate electrode 25, an interlayer insulating film 26, a source electrode 27, a drain electrode 28, and a protective film 29.

The TFT 50 has a structure in which the substrate 21, the buffer layer 22, and the channel layer (crystalline oxide semiconductor film) 11 are laminated in the stated order. A high-resistance region 11B is present in the center portion of the channel layer 11, and the gate insulating film 24 (insulating film) and the gate electrode 25 are laminated on the high-resistance region 11B in the stated order. The gate insulating film 24 is an insulating film that interrupts conduction between the gate electrode 25 and the crystalline oxide semiconductor film 11.

Low-resistance regions 11A-1 and 11A-2 of the channel layer 11 are present on both sides of the high-resistance region 11B. The low-resistance regions 11A-1 and 11A-2 and the gate electrode 25 are covered with the ITO layer 23 and the interlayer insulating film 26. The ITO layer 23 is used at the time of the formation of the low-resistance regions of the channel layer 11.

Specifically, the low-resistance regions 11A-1 and 11A-2 are formed by causing a target portion of the channel layer 11 to have low resistance by performing heat treatment (annealing) in the presence of the ITO layer 23. A region that is not covered by the ITO layer 23 is maintained as the high-resistance region B.

The source electrode 27 and the drain electrode 28 are connected to the low-resistance regions 11A-1 and 11A-2, respectively, through contact holes formed in the ITO layer 23 and the interlayer insulating film 26. The source electrode 27 and the drain electrode 28 are conductive terminals for allowing a source current and a drain current to flow to the channel layer 11.

The protective film 29 is arranged so as to cover the TFT constituent layers, such as the interlayer insulating film 26, the source electrode 27, and the drain electrode 28.

The TFT of this embodiment may be modified with a known configuration.

For example, although not shown in FIG. 3, a light shield layer 31 may be formed between the substrate 21 and the buffer layer 22 in the TFT 50 as illustrated in FIG. 4, or the light shield layer 31 may be formed as an intermediate layer of the buffer layer 22 in which a plurality of layers are laminated.

FIG. 4 is a schematic sectional view of another example of the TFT of this aspect.

ATFT 51 has the same configuration as that of the TFT 50 except that the light shield layer 31 is arranged between the substrate 21 and the buffer layer 22. The light shield layer 31 is formed in order to suppress the malfunction of the TFT caused by light. The light shield layer may be connected to the source electrode 27 or may be connected to the gate electrode 25.

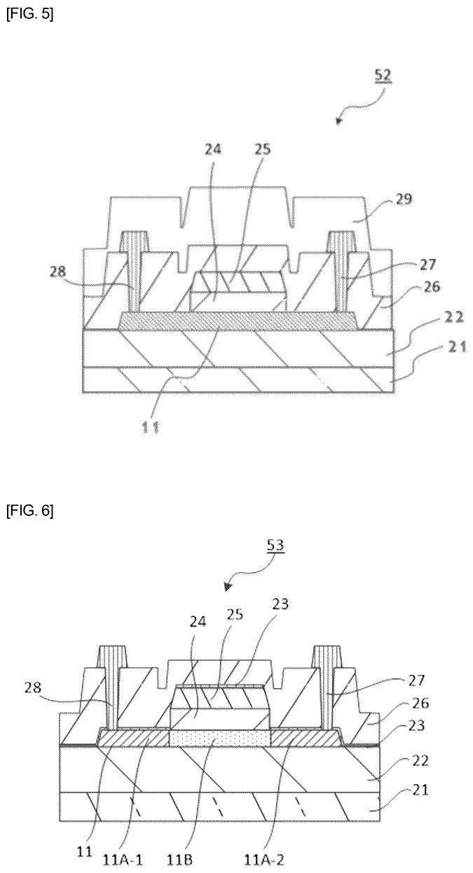

In addition, in FIG. 3, as an example of the TFT of the present disclosure, there is illustrated a configuration example in which both end sides of the channel layer 11, that is, the vicinities of the regions to which the source electrode 27 and the drain electrode 28 are connected are the low-resistance regions 11A of the crystalline oxide semiconductor film, and the region in contact with the lower surface of the gate insulating film 24 is the high-resistance region 11B. However, the TFT of the present disclosure is not limited to this configuration. That is, the TFT of the present disclosure may use a crystalline oxide semiconductor film having a uniform resistance value in a planar direction as the channel layer 11. In this case, the ITO layer 23 may not be formed as illustrated in FIG. 5.

FIG. 5 is a schematic sectional view of another example of the TFT of this embodiment.

A TFT 52 has the same configuration as that of the TFT 50 except that: the channel layer (crystalline oxide semiconductor film) 11 is a layer having no boundary of a resistance value (the channel layer (crystalline oxide semiconductor film) 11 is not divided into the low-resistance regions 11A and the high-resistance region 11B); and the ITO layer 23 is not formed.

In this embodiment, when the TFT is a small TFT, the crystalline oxide semiconductor film serving as the channel layer with respect to the source electrode and the drain electrode has a channel length (L length; length in the source electrode 27 and drain electrode 28 direction in a contact region between the channel layer 11 and the gate insulating layer 24 in FIG. 3) of 1 μm or more and 50 μm or less and a channel width (W length; length in a direction perpendicular to the source electrode 27 and drain electrode 28 direction in the contact region between the channel layer 11 and the gate insulating layer 24 in FIG. 3) of 1 μm or more and 80 μm or less.

The TFT of this embodiment may be modified with a known configuration.

A material for forming the substrate is not particularly limited, and any material that is generally used may be selected. There may be used, for example, a glass substrate, a ceramic substrate, a quartz substrate, or a sapphire substrate. In addition, for example, a single crystal semiconductor substrate, such as silicon or silicon carbide, a polycrystal semiconductor substrate, a compound semiconductor substrate such as silicon germanium, or a silicon in insulator (SIO) substrate may be applied, or these substrates each having a semiconductor element arranged thereon may be used as the substrate.

In addition, a flexible substrate may be used as the substrate. As a method of arranging the TFT on the flexible substrate, there is given a method of directly producing the TFT on the flexible substrate, and there is also given a method involving producing the TFT on a non-flexible substrate, then peeling the TFT, and setting the TFT on the flexible substrate. In this case, a release layer may be arranged between the non-flexible substrate and the TFT.

The buffer layer 22 may be formed of a single layer or two or more laminated layers. In addition, a metal layer may be formed between the buffer layer 22 and the substrate 21.

It is preferred that the channel layer 11 and the buffer layer 22 be in direct contact with each other as illustrated in FIG. 3.

A material for forming the buffer layer is not particularly limited, and any material that is generally used may be selected. In addition, a laminated film may be used as the buffer layer. There may be used, for example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN. The oxidation numbers of the respective materials may be varied.

The light shield layer 31 may be connected to the source electrode 27 or may be connected to the gate electrode 25.

A material for forming the light shield layer is not particularly limited, and any material that is generally used may be selected. Specific examples thereof include metal electrodes made of Al, Ag, Cu, Cr, Ni, Co, Mo, Au, Ti, Zr, Ru, Y, Nb, Ta, and W, and metal electrodes made of alloys containing two or more kinds of these metals. In addition, a laminated electrode of two or more layers may be used.

In FIG. 4, a second buffer layer may be arranged between the light shield layer 31 and the substrate 21. A material for forming the second buffer layer is also not particularly limited, and any material that is generally used may be selected. In addition, a laminated film may be used as the second buffer layer. As a material for the second buffer layer, there may be used, for example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN. The oxidation numbers of the respective materials may be varied.

The material described as a material for the insulating film may be used as a material for forming the gate insulating film.

Materials for forming the drain electrode, the source electrode, and the gate electrode are not particularly limited, and any materials that are generally used may be selected. Specifically, for example, there are given transparent electrodes made of ITO, IZO, ZnO, and SnO₂, metal electrodes made of Al, Ag, Cu, Cr, Ni, Co, Mo, Au, Ti, Zr, Ru, Y, Nb, Ta, and W, or metal electrodes made of alloys containing two or more kinds of these metals. In addition, a laminated electrode of two or more layers may be used.

A material for each interlayer insulating film is also not particularly limited, and any material that is generally used may be selected. In addition, a laminated film may be used as the interlayer insulating film.

For example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN may be used. The oxidation number of the respective materials may be varied.

Irrespective of the structure of the TFT, the protective film is preferably arranged on the drain electrode, the source electrode, and the conductive region. When the protective film is arranged, the TFT is easily improved in durability even when driven for a long period of time.

A method of producing an insulating films such as the buffer layer, the gate insulating film, or the interlayer insulating film is not particularly limited. Examples of the production method include PE-CVD, ALD, PLD, MO-CVD, RF sputtering, ICP sputtering, reactive sputtering, ICP-CVD, ion plating, a sol-gel method, a coating method, and mist CVD. Tetraethoxysilane (TEOS) may be used as the kind of gas in the PE-CVD in addition to silane (SiH₄).

For example, when an insulating film is formed by the PE-CVD, the process may become a high-temperature process. In addition, the protective film or the insulating film often contains an impurity gas immediately after the film formation, and is hence preferably subjected to the heat treatment (annealing treatment). When the impurity gas is removed by the heat treatment, a stable protective film or insulating film is obtained, which makes it easy to form a highly durable TFT.

The saturation mobility of the TFT is preferably 10.0 cm²/V·s or more, more preferably 20.0 cm²/V·s or more.

When the saturation mobility of the TFT is set to 10.0 cm²/V·s or more, a higher resolution, a higher frame rate, and a larger area of a display can be achieved.

The saturation mobility of the TFT is determined from transmission characteristics in the case of the application of a drain voltage of 20 V. A method of measuring the saturation mobility of the TFT is described in detail in Examples.

The threshold voltage (Vth) is preferably −3.0 V or more and 3.0 V or less, more preferably −2.0 V or more and 2.0 V or less, still more preferably −1.0 V or more and 1.0 V or less. When the threshold voltage (Vth) is −3.0 V or more and 3.0 V or less, the threshold voltage (Vth) can be corrected to Vth=0 V by installing a Vth correction circuit on the TFT. When the TFT thus obtained is installed into a panel, a display can be driven without uneven brightness and burn-in.

The threshold voltage (Vth) may be defined as a Vg when Id=10⁻⁹ A based on the graph of transmission characteristics.

An on-off ratio is preferably 10⁶ or more, more preferably 10⁷ or more, still more preferably 10⁸ or more. When the on-off ratio is 10⁶ or more, a liquid crystal display can be driven. When the on-off ratio is 10⁸ or more, an organic EL device having a large contrast can be driven. In addition, when the on-off ratio can be set to 10¹⁰ or more, and the off-current can be set to 10⁻¹² A or less, a display element excellent in low consumption that can be driven at a low frequency of about 1 Hz can be provided.

The on-off ratio is determined by setting an off-current value to a value of Id when Vd=10 V and Vg=−10 V and setting an on-current value to a value of Id when Vd=10 V and Vg=20 V to determine a ratio [on-current value/off-current value].

The off-current value is preferably 10⁻¹⁰ A or less, more preferably 10⁻¹¹ A or less, still more preferably 10⁻¹² A or less. When the off-current value is 10⁻¹⁰ A or less, an organic EL having a large contrast can be driven. In addition, when the TFT is used as a transfer transistor or a reset transistor for a CMOS image sensor, the retention time of an image can be lengthened, and sensitivity can be improved.

The TFT according to this embodiment may be suitably used for solar cells, liquid crystal elements, organic electroluminescence elements, inorganic electroluminescence elements, and other display elements, and power semiconductor elements, touch panels, and other electronic devices.

The thin film transistor according to this embodiment may be applied to various integrated circuits including a field effect transistor (MOSFET or MESFET), a logic circuit, a memory circuit, and a differential amplification circuit, and the various integrated circuits may be applied to an electronic device, an electric device, a vehicle, a power engine, and the like. Further, the thin film transistor according to this embodiment may be applied not only to the field effect transistor but also to an electrostatic induction transistor and a Schottky barrier transistor.

The thin film transistor according to this embodiment may be suitably used for a display device such as a portable or in-vehicle display device, a solid-state image sensor, and the like. Further, the thin film transistor according to this embodiment may also be suitably used as a transistor for a flat panel detector for an X-ray image sensor for medical use.

In addition, the crystalline oxide semiconductor film according to this embodiment may be applied to a Schottky diode, a resistance change type memory, and a resistive element.

### EXAMPLES

The present disclosure is specifically described byway of Examples. The present disclosure is not limited to Examples.

### [Production of Self-Aligned Top-Gate Structure Small TFT]

### Example 1

A thin film transistor (TFT) 53 illustrated in FIG. 6 was produced through the following steps. The TFT 53 has the same configuration as that of the TFT 50 illustrated in FIG. 3 except that the protective layer 29 is absent.

### (1) Formation of Buffer Layer 22

A SiOₓ layer (buffer layer 22) having a thickness of 300 nm was formed on an alkali-free glass substrate 21 (EAGLE XG manufactured by Corning Incorporated) having a diameter of 4 inches by sputtering through use of a sputtering target of SiO₂. Sputtering conditions are as described below.
Substrate temperature: 25° C.
Ultimate pressure: 8.5×10⁻⁵ Pa
Atmospheric gas: Ar
Sputtering pressure (total pressure): 0.4 Pa
Input voltage: RF 300 W
Distance between substrate (S) and target (T): 70 mm

### (2) Formation of Oxide Thin Film

Next, a channel layer was formed by sputtering through use of an oxide sputtering target obtained from a raw material mixture having a loaded composition ratio shown in Table 1-1. A metal composition ratio (unit: at %) in the oxide sputtering target is shown in Table 1-1.

Film formation conditions in the sputtering and the thickness of the channel layer are shown in Table 1-1. Sputtering conditions except those shown in Table 1-1 are as described below.
Substrate temperature: 25° C.
Ultimate pressure: 1.0×10⁻⁴ Pa
Atmospheric gas: mixed gas of Ar and H₂O
Sputtering pressure (total pressure): 0.5 Pa
Input voltage: DC 300 W
Distance between substrate (S) and target (T): 70 mm

### (3) Formation of Channel Layer 11

Next, the oxide thin film was patterned into an island shape by photolithography to form the channel layer 11. First, a film of a photoresist was formed on the oxide thin film. AZ1500 (manufactured by AZ Electronic Materials SA) was used as the photoresist. The film was exposed to light through a photomask in which a pattern was formed into a width of 50 μm by a length of 20 μm. After the exposure, development was performed with tetramethylammonium hydroxide (TMAH). After the development, the oxide thin film was etched with oxalic acid (ITO-06N manufactured by Kanto Chemical Co., Inc.). After the etching, the photoresist was peeled off. Thus, a substrate with a patterned oxide thin film (channel layer 11) was obtained.

### (4) Annealing

Next, the substrate having the channel layer 11 formed thereabove was placed in a furnace. The temperature inside the furnace was increased to 350° C. at 10° C./min in the atmosphere, and was then held for 1 hour. After the temperature inside the furnace was held at 350° C. for 1 hour, the furnace was allowed to cool naturally. After the temperature inside the furnace returned to room temperature, the substrate was removed from the furnace.

### (5) Surface Treatment

Next, the channel layer 11 was subjected to surface treatment by the following method.

First, a SiOₓ layer (treated film) having a thickness of 10 nm was formed by sputtering through use of a sputtering target of SiO₂. Sputtering conditions are as described below.
Substrate temperature: 25° C.
Ultimate pressure: 8.5×10⁻⁵ Pa
Atmospheric gas: mixed gas of Ar+O₂ (O₂ flow rate: 30%)
Sputtering pressure (total pressure): 0.4 Pa
Input voltage: RF 300 W
Distance between substrate (S) and target (T): 70 mm

The above-mentioned SiOₓ layer (treated film) is integrated with a SiOₓ layer having a thickness of 100 nm to be formed in “(7) Formation of Gate Insulating Film 24” described later to function as the gate insulating film 24 of the TFT.

The thickness of the SiOₓ layer formed by the sputtering is shown in the row of “Thickness” of “Surface Treatment” in Table 1-1.

(6) Annealing after Surface Treatment

Next, the substrate subjected to the surface treatment was placed in a furnace. The temperature inside the furnace was increased to 400° C. at 10° C./min in the atmosphere, and was then held for 1 hour. After the temperature inside the furnace was held at 400° C. for 1 hour, the furnace was allowed to cool naturally. After the temperature inside the furnace returned to room temperature, the substrate was removed from the furnace.

### (7) Formation of Gate Insulating Film 24

Next, a SiOₓ layer (gate insulating film 24) having a thickness of 100 nm was formed by sputtering through use of a sputtering target of SiO₂. Sputtering conditions are as described below.
Substrate temperature: 25° C.
Ultimate pressure: 8.5×10⁻⁵ Pa
Atmospheric gas: mixed gas of Ar+O₂ (O₂ flow rate: 30%)
Sputtering pressure (total pressure): 0.4 Pa
Input voltage: RF 300 W
Distance between substrate (S) and target (T): 70 mm

As a result, the SiOₓ layer (thickness: 100 nm) formed in this step is formed, and is integrated with the SiOₓ layer (thickness: 10 nm) formed in the above-mentioned “Surface Treatment” to become the gate insulating film 24. The total thickness of the gate insulating film 24 was 110 nm.

### (8) Annealing of Gate Insulating Film 24

Next, the substrate having the gate insulating film 24 formed thereabove was placed in a furnace. The temperature inside the furnace was increased to 400° C. at 10° C./min in the atmosphere, and was then held for 1 hour. After the temperature inside the furnace was held at 400° C. for 1 hour, the furnace was allowed to cool naturally. After the temperature inside the furnace returned to room temperature, the substrate was removed from the furnace.

### (9) Formation of Gate Electrode 25

Next, a Mo film having a thickness of 150 nm was formed through use of a sputtering target of Mo. Sputtering conditions are as described below.
Substrate temperature: 25° C.
Ultimate pressure: 8.5×10⁻⁵ Pa
Atmospheric gas: Ar
Sputtering pressure (total pressure): 0.4 Pa
Input voltage: DC 100 W
Distance between substrate (S) and target (T): 70 mm

### (10) Patterning of Gate Electrode 25 and Gate Insulating Film 24

Next, the Mo film and the gate insulating film 24 were patterned into an island shape by photolithography. First, a film of a photoresist was formed on the channel layer. AZ1500 (manufactured by AZ Electronic Materials SA) was used as the photoresist. The film was exposed to light through a photomask in which a pattern was formed. After the exposure, development was performed with tetramethylammonium hydroxide (TMAH). After the development, a gate electrode 25 was formed by etching the Mo film with a mixed acid of phosphoric acid, nitric acid, and acetic acid (phosphoric-acetic-nitric acid (PAN)).

Then, the gate insulating film 24 was etched with buffered hydrofluoric acid (BHF) and patterned into an island shape.

Next, after the photoresist was peeled off, a region in which the channel layer 11 was exposed was etched by a thickness of 10 nm through use of oxalic acid (ITO-06N manufactured by Kanto Chemical Co., Inc.), followed by cleaning.

The dimensions of a portion in which the resultant gate electrode layer 25 and gate insulating film 24 overlapped with the channel layer 11 were a width of 10 μm by a length of 28 μm.

### (11) Low-Resistance Treatment

Low-resistance regions A (11A-1 and 11A-2) were formed in the channel layer 11 by self-alignment using the gate electrode 25. An ITO layer 23 having a thickness of 2 nm was formed through use of a sputtering target of ITO. Sputtering conditions are as described below.
Substrate temperature: 25° C.
Ultimate pressure: 8.5×10⁻⁵ Pa
Atmospheric gas: mixed gas of Ar+O₂ (O₂ flow rate: 2%)
Sputtering pressure (total pressure): 0.4 Pa
Input voltage: DC 50 W
Distance between substrate (S) and target (T): 70 mm

Next, the substrate after the low-resistance treatment was placed in a furnace. The temperature inside the furnace was increased to 350° C. at 10° C./min in the atmosphere, and was then held for 1 hour. Thus, the substrate was annealed. After the temperature inside the furnace was held at 350° C. for 1 hour, the furnace was allowed to cool naturally. After the temperature inside the furnace returned to room temperature, the substrate was removed from the furnace.

### (12) Formation of Interlayer Insulating Film 26

Next, a SiOₓ layer (interlayer insulating film 26) having a thickness of 150 nm was formed by sputtering through use of a sputtering target of SiO₂. Sputtering conditions are as described below.
Substrate temperature: 25° C.
Ultimate pressure: 8.5×10⁻⁵ Pa
Atmospheric gas: mixed gas of Ar+O₂ (O₂ flow rate: 30%)
Sputtering pressure (total pressure): 0.4 Pa
Input voltage: RF 100 W
Distance between substrate (S) and target (T): 70 mm

### (13) Formation of Contact Hole in Interlayer Insulating Film 26

The substrate having the interlayer insulating film 26 formed thereabove was coated with a photoresist AZ1500 (manufactured by AZ Electronic Materials SA) and exposed to light through a photomask. After that, development was performed with tetramethylammonium hydroxide (TMAH). After the development, a contact hole having a width of 12 μm and a length of 18 μm was formed with buffered hydrofluoric acid (BHF).

### (14) Formation of Source Electrode 27 and Drain Electrode 28

The source electrode 27 and the drain electrode 28 were patterned by a lift-off process through use of an image reversal resist AZ5214 and a photomask. The image reversal resist AZ5214 was exposed to light through a photomask. The resist was subjected to a reversal baking step, and was then subjected to full exposure and development with TMAH. A Mo layer having a thickness of 150 nm was formed on the substrate with the patterned resist under the following sputtering conditions.
Substrate temperature: 25° C.
Ultimate Pressure: 8.5×10⁻⁵ Pa
Atmospheric gas: Ar
Sputtering pressure (total pressure): 0.4 Pa
Input voltage: DC 100 W
Distance between substrate (S) and target (T): 70 mm

After that, the substrate having the Mo layer formed thereabove was lifted off in acetone. Thus, the source electrode 27 and the drain electrode 28 were patterned.

### (15) Final Annealing

Finally, the resultant was annealed at 300° C. for 1 hour in a N₂ atmosphere to provide a self-aligned top-gate structure small TFT.

The production conditions for the TFT are summarized in Tables 1-1 to 1-3 and 2.

### Example 2

A TFT was produced in the same manner as in Example 1 except that the thickness of the channel layer formed in “(2) Formation of Oxide Thin Film” was changed as shown in Table 1-1.

### Examples 3 to 5

Each TFT was produced in the same manner as in Example 1 except that the thickness of the SiOₓ layer (treated film) formed in “(5) Surface Treatment” was changed as shown in Table 1-1.

### Example 6

A TFT was produced in the same manner as in Example 1 except that “(5) Surface Treatment” was performed by chemical vapor deposition (CVD) treatment instead of sputtering.

The chemical vapor deposition (CVD) treatment was performed by the following method.

First, the substrate after “(4) Annealing” was performed was set in a plasma CVD device. The substrate was held at 350° C., and SiH₄ at a flow rate of 2 sccm, N₂O at a flow rate of 100 sccm, and N₂ at a flow rate of 120 sccm were introduced under a pressure of 110 Pa to form a SiOₓ layer having a thickness of 10 nm.

### Example 7

A SiNₓ layer having a thickness of 10 nm was formed in the same manner as in Example 1 except that a sputtering target of SiNₓ was used instead of the sputtering target of SiO₂ in “(5) Surface Treatment.” The other steps were performed in the same manner as in Example 1. Thus, a TFT was produced.

### Example 8

An Al₂O₃ layer having a thickness of 10 nm was formed in the same manner as in Example 1 except that a sputtering target of Al₂O₃ was used instead of the sputtering target of SiO₂ in “(5) Surface Treatment.” The other steps were performed in the same manner as in Example 1. Thus, a TFT was produced.

### Example 9

A TFT was produced in the same manner as in Example 1 except that: plasma oxidation treatment with N₂O using a PE-CVD device was performed instead of the film formation by sputtering in “(5) Surface Treatment (Film Formation Treatment)” in Example 1; and subsequent “(6) Annealing after Surface Treatment” was not performed. The plasma oxidation treatment with N₂O was performed by introducing N₂O at a gas pressure of 133 Pa at normal temperature under the conditions of a power of 50 Wand a treatment time of 1 minute.

In Table 1-2, the description “No film formation at time of surface treatment” in the row of “Thickness” of “Surface Treatment” in Example 9 means that no film is formed by the plasma oxidation treatment with N₂O.

In Example 9, the SiOₓ layer having a thickness of 100 nm formed in “(7) Formation of Gate Insulating Film 24” forms the gate insulating film 24.

### Example 10

A TFT was produced in the same manner as in Example 1 except that, in “(2) Formation of Oxide Thin Film,” the composition ratios of the sputtering target to be used for the formation of the channel layer were changed as shown in Table 1-2, and the oxygen partial pressure and water partial pressure of the film formation atmospheric gas at the time of the formation of the channel layer were changed as shown in Table 1-2.

### Example 11

A channel layer was formed in the same manner as in Example 10 except that, in “(2) Formation of Oxide Thin Film,” the composition ratios of the sputtering target to be used for the formation of the channel layer were changed as shown in Table 1-2.

In addition, a SiO₃ layer (treated film) having a thickness of 10 nm was formed in the same manner as in Example 1 except that, in “(5) Surface Treatment,” the O₂ flow rate of 30% of the film formation atmospheric gas at the time of the film formation treatment was changed to a H₂O flow rate of 1% of the film formation atmospheric gas.

The other steps were performed in the same manner as in Example 1. Thus, a TFT was produced.

### Examples 12 to 16

Each TFT was produced in the same manner as in Example 1 except that, in “(2) Formation of Oxide Thin Film,” the composition ratios of the sputtering target to be used for the formation of the channel layer were changed as shown in Table 1-2, and the oxygen partial pressure and water partial pressure of the film formation atmosphere gas at the time of the formation of the channel layer were changed as shown in Table 1-2.

### Comparative Example 1

A TFT was produced in the same manner as in Example 1 except that “(5) Surface Treatment” and “(6) Annealing after Surface Treatment” were not performed.

### Comparative Example 2

A TFT was produced in the same manner as in Example 1 except that the thickness of the SiO₂ layer (treated film) formed in “(5) Surface Treatment” was changed as shown in Table 1-3.

### Comparative Example 3

A TFT was produced in the same manner as in Example 1 except that “(6) Annealing after Surface Treatment” was not performed.

### Comparative Example 4

A TFT was produced in the same manner as in Example 9 except that “(6) Annealing after Surface Treatment” was performed in the same manner as in Example 1 after “(5) Surface Treatment” was performed.

In Comparative Example 4, the SiO₂ layer having a thickness of 100 nm formed in “(7) Formation of Gate Insulating Film 24” forms the gate insulating film 24.

The TFTs obtained in Examples and Comparative Examples were evaluated as described below. The results are shown in Tables 1-1 to 1-3.

### (a) Evaluation Regarding Laminate Structure of TFT

### (1) Measurement of A/B (EDX Test)

The average value of A/B represented by the following formula (1) in the laminate structure of the gate insulating film and the channel layer (crystalline oxide semiconductor film) was measured by transmission electron microscopy-energy dispersive X-ray spectroscopy (TEM-EDX).

$$1.25 \leq ( average value of A / B ) \leq 1.75 \qquad ( 1 )$$

A in the formula (1) represents the number of oxygen atoms. B in the formula (1) represents the number of detectable cation atoms that exist in a state of being bonded to the oxygen atoms. The cation atoms are cationic atomic species contained in the laminate structure of the gate insulating film and the channel layer (crystalline oxide semiconductor film) in an amount of 1 at % or more.

The measurement of the average value of A/B in the laminate structure by the TEM-EDX was performed as described below.

First, the TFT obtained in each of Examples and Comparative Examples was processed with a focused ion beam (FIB) at an acceleration voltage of from 20 kV to 30 kV with a composite beam processing and observation device (“JIB-4700F” manufactured by JEOL Ltd.). After that, a thin film sample for cross-sectional TEM observation was picked up by a micro-sampling method at an acceleration voltage of 40 kV with a focused ion beam (FIB) processing and observation device (“FB-2100” manufactured by Hitachi High-Technologies Corporation).

The thin film sample for cross-sectional TEM observation was produced as a thin film formed of a laminate structure with a thickness region having an approximately equal thickness on the gate insulating film side and the channel layer side centered on the interface between the gate insulating film and the channel layer so that the thin film samples of all Examples and Comparative Examples had the same thickness after processing (about 70 nm).

Next, the thin film sample for cross-sectional TEM observation was observed by cross-sectional TEM, and EDX analysis was performed on the field of view centered on the interface between the gate insulating film and the channel layer, including a thickness region of about 130 nm on each of the gate insulating film side and the channel layer side (see FIG. 2).

The EDX analysis was performed with an energy dispersive X-ray analyzer (“JED-2300T” manufactured by JEOL Ltd.) under the following conditions.
Acceleration voltage: 200 kV
Measurement mode: STEM mode
Spot diameter: 0.16 nm
Measurement interval: 1 nm

The EDX analysis was performed by selecting cation atoms that exist in a state of being bonded to oxygen atoms and the oxygen atoms as elements to be detected (detectable elements), and performing line analysis on a range of about 130 nm centered on the interface between the gate insulating film and the channel layer in the lamination direction of the gate insulating film and the channel layer.

Specifically, In, Ga, Si, Al, and Mo were selected as the cation atoms that exist in a state of being bonded to the oxygen atoms.

Regarding EDX spectral intensities obtained from the EDX line analysis, at % of A (oxygen atoms) and at % of B (detectable cation atoms that exist in a state of being bonded to the oxygen atoms) for each measurement point were automatically calculated through use of initial set values with exclusive software of an energy dispersive X-ray analyzer (“JED-2300T” manufactured by JEOL Ltd.). Thus, A/B for each measurement point represented by the formula (1) was calculated.

The average value of A/B was calculated by performing arithmetic averaging of the A/B values obtained at respective measurement points in the above-mentioned EDX line analysis with respect to a specified thickness range.

In addition, regarding the channel layer (crystalline oxide semiconductor film) region in the TFT, the above-mentioned EDX line analysis was performed on all cations contained in the laminate structure, and a region showing a value of the largest In concentration in the cation concentrations of the respective cations (concentrations of the respective cations with respect to all detectable atoms contained in the channel layer) was defined as the channel layer (crystalline oxide semiconductor film) region.

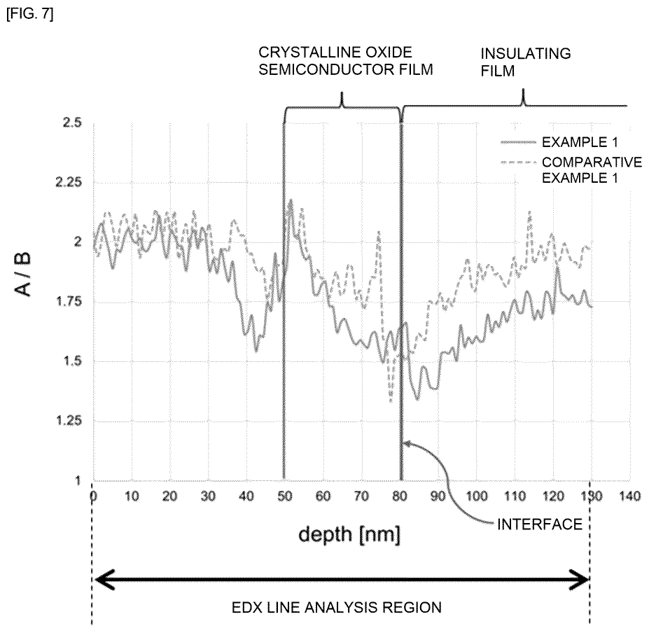

FIG. 7 shows EDX spectra obtained by the EDX line analysis of the thin film samples for cross-sectional TEM observation in Example 1 and Comparative Example 1. In FIG. 7, the horizontal axis represents the depth position in the lamination direction of the laminate structure, and the vertical axis represents A/B.

### (B) Evaluation Regarding Performance of TFT

The resultant TFT was measured with a semiconductor parameter analyzer (“B1500” manufactured by Agilent) at room temperature under a light-shielding environment (inside a shield box). A drain voltage (Vd) of 20 V was applied. A current value Id was measured at a gate voltage (Vg) of from −5 V to 20 V in increments of 0.1 V for the application of the Vd. Thus, Id-Vg characteristics were obtained.

Various parameters calculated from the Id-Vg characteristics are shown in Tables 1-1 to 1-3. A calculation method for each parameter is as described below.

### (a) Maximum Value of Saturation Mobility

For the maximum value of a saturation mobility at the time of the application of a Vd of 20 V, a graph of Id-Vg characteristics was created, a transconductance (Gm) at each Vg was calculated, and the saturation mobility (μₛₐₜ) was derived with the formula of a saturation region. Specifically, the Gm was calculated by the following mathematical formula (c1).

$$Gm = \partial ( \sqrt{Id} ) / \partial ( V g ) \qquad ( c1 )$$

Further, the μₛₐₜ was calculated by the following formula (c) of the saturation region.

$${μ}_{sat} = ( 2 \cdot Gm \cdot L ) / ( W \cdot Ci ) \qquad ( c )$$

In the formula (c), L represents a channel length (L length), and W represents a channel width (W length).

Further, the maximum value of the μₛₐₜ at a Vg of from 0 V to 20 V was calculated from each Vg-μₛₐₜ graph.

### (b) Reliability of Self-Aligned Small TFT (Exposure Test)

The reliability of the TFT was evaluated by a stress test. A negative bias illumination temperature stress (NBITS) test was performed as the stress test.

In the NBITS test, a Vg of −20V was applied at 50° C. while light having an illuminance of 4,500 nits was radiated as LED light from the interlayer insulating film 26 side, and a threshold voltage (Vth) after the elapse of 10,000 seconds was compared to that before the test, and a difference therebetween was defined as ΔVth.

TABLE 1-1

| | | | Example 1 | Example 2 | Example 3 | Example 4 |
|---|---|---|---|---|---|---|
| Sputtering | Loaded composition ratio | In₂O₃ | 89.0 | 89.0 | 89.0 | 89.0 |
| target | [mass %] | Ga₂O₃ | 9.8 | 9.8 | 9.8 | 9.8 |
| | | Other additive elements | Al₂O₃ 1.2 | Al₂O₃ 1.2 | Al₂O₃ 1.2 | Al₂O₃ 1.2 |
| | Metal composition ratio | In | 83.2 | 83.2 | 83.2 | 83.2 |
| | [at %] | Ga | 13.5 | 13.5 | 13.5 | 13.5 |
| | | Other additive elements | Al 3.3 | Al 3.3 | Al 3.3 | Al 3.3 |
| TFT | Formation of channel layer | Pressure at time of film formation [Pa] | 0.5 | 0.5 | 0.5 | 0.5 |
| production | | Oxygen partial pressure at time of film | 0.05 | 0.05 | 0.05 | 0.05 |
| conditions | | formation [Pa] | | | | |
| | | Water partial pressure at time of film | 0.00 | 0.00 | 0.00 | 0.00 |
| | | formation [Pa] | | | | |
| | | Magnetic flux density [G] | 600 | 600 | 600 | 600 |
| | | Thickness [nm] | 30 | 10 | 30 | 30 |
| | Channel layer patterning | Semiconductor etching | Oxalic acid | Oxalic acid | Oxalic acid | Oxalic acid |
| | Annealing | Temperature increase pattern [° C./min] | 10 | 10 | 10 | 10 |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Surface treatment | Treatment species | SiO₂ | SiO₂ | SiO₂ | SiO₂ |
| | | Treatment method | Sputtering | Sputtering | Sputtering | Sputtering |
| | | Thickness [nm] | 10 | 10 | 5 | 20 |
| | Annealing after surface | Temperature increase pattern [° C./min] | 10 | 10 | 10 | 10 |
| | treatment | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | Formation of gate | Gate insulating film | SiO₂ | SiO₂ | SiO₂ | SiO₂ |
| | insulating film | Thickness [nm] | 100 | 100 | 100 | 100 |
| | Annealing | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | | | atmosphere | atmosphere | atmosphere | atmosphere |
| | Refer to Table 2 for continuation of TFT production conditions | | | | | |
| Evaluation | Average value of A/B*⁾ | Insulating film | 1.57 | 1.55 | 1.61 | 1.61 |
| results | | Channel layer | 1.66 | 1.63 | 1.48 | 1.71 |
| | TFT characteristics | Maximum value of saturation mobility [cm²/Vs] | 40 | 41 | 42 | 45 |
| | | Optical reliability (NBTIS) ΔVth [V] | 0.5 | 0.4 | 0.6 | 0.6 |

| | | | Example 5 | Example 6 | Example 7 | Example 8 |
|---|---|---|---|---|---|---|
| Sputtering | Loaded composition ratio | In₂O₃ | 89.0 | 89.0 | 89.0 | 89.0 |
| target | [mass %] | Ga₂O₃ | 9.8 | 9.8 | 9.8 | 9.8 |
| | | Other additive elements | Al₂O₃ 1.2 | Al₂O₃ 1.2 | Al₂O₃ 1.2 | Al₂O₃ 1.2 |
| | Metal composition ratio | In | 83.2 | 83.2 | 83.2 | 83.2 |
| | [at %] | Ga | 13.5 | 13.5 | 13.5 | 13.5 |
| | | Other additive elements | Al 3.3 | Al 3.3 | Al 3.3 | Al 3.3 |
| TFT | Formation of channel layer | Pressure at time of film formation [Pa] | 0.5 | 0.5 | 0.5 | 0.5 |
| production | | Oxygen partial pressure at time of film | 0.05 | 0.05 | 0.05 | 0.05 |
| conditions | | formation [Pa] | | | | |
| | | Water partial pressure at time of film | 0.00 | 0.00 | 0.00 | 0.00 |
| | | formation [Pa] | | | | |
| | | Magnetic flux density [G] | 600 | 600 | 600 | 600 |
| | | Thickness [nm] | 30 | 30 | 30 | 30 |
| | Channel layer patterning | Semiconductor etching | Oxalic acid | Oxalic acid | Oxalic acid | Oxalic acid |
| | Annealing | Temperature increase pattern [° C./min] | 10 | 10 | 10 | 10 |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Surface treatment | Treatment species | SiO₂ | SiO₂ | SiNₓ | Al₂O₃ |
| | | Treatment method | Sputtering | CVD | Sputtering | Sputtering |
| | | Thickness [nm] | 30 | 10 | 10 | 10 |
| | Annealing after surface | Temperature increase pattern [° C./min] | 10 | 10 | 10 | 10 |
| | treatment | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | Formation of gate | Gate insulating film | SiO₂ | SiO₂ | SiO₂ | SiO₂ |
| | insulating film | Thickness [nm] | 100 | 100 | 100 | 100 |
| | Annealing | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | | | atmosphere | atmosphere | atmosphere | atmosphere |
| | Refer to Table 2 for continuation of TFT production conditions | | | | | |
| Evaluation | Average value of A/B*⁾ | Insulating film | 1.72 | 1.52 | 1.32 | 1.62 |
| results | | Channel layer | 1.8 | 1.58 | 1.8 | 1.55 |
| | TFT characteristics | Maximum value of saturation mobility [cm²/Vs] | 50 | 38 | 44 | 39 |
| | | Optical reliability (NBTIS) ΔVth [V] | 0.7 | 0.1 | 0.9 | 0.2 |

TABLE 1-2

| | | | Example 9 | Example 10 | Example 11 | Example 12 |
|---|---|---|---|---|---|---|
| Sputtering | Loaded composition ratio | In₂O₃ | 89.0 | 100.0 | 81.6 | 81.6 |
| target | [mass %] | Ga₂O₃ | 9.8 | 0.0 | 18.4 | 18.4 |
| | | Other additive elements | Al₂O₃ 1.2 | 0.0 | 0.0 | 0.0 |
| | Metal composition ratio | In | 83.2 | 100.0 | 75.0 | 75.0 |
| | [at %] | Ga | 13.5 | 0.0 | 25.0 | 25.0 |
| | | Other additive elements | Al 3.3 | 0.0 | 0.0 | 0.0 |
| TFT | Formation of channel layer | Pressure at time of film formation [Pa] | 0.5 | 0.5 | 0.5 | 0.5 |
| production | | Oxygen partial pressure at time of film formation | 0.05 | 0.00 | 0.00 | 0.05 |
| conditions | | [Pa] | | | | |
| | | Water partial pressure at time of film formation | 0.00 | 0.01 | 0.01 | 0.00 |
| | | [Pa] | | | | |
| | | Magnetic flux density [G] | 600 | 600 | 600 | 600 |
| | | Thickness [nm] | 30 | 30 | 30 | 30 |
| | Channel layer patterning | Semiconductor etching | Oxalic acid | Oxalic acid | Oxalic acid | Oxalic acid |
| | Annealing | Temperature increase pattern [° C./min] | 10 | 10 | 10 | 10 |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Surface treatment | Treatment species | N₂O | SiO₂ | SiO₂ | SiO₂ |
| | | Treatment method | Plasma | Sputtering | Sputtering | Sputtering |
| | | | oxidation | | | |
| | | | treatment | | | |
| | | Thickness [nm] | No film | 10 | 10 | 10 |
| | | | formation at | | | |
| | | | time of | | | |
| | | | surface | | | |
| | | | treatment | | | |
| | Annealing after surface | Temperature increase pattern [° C./min] | — | 10 | 10 | 10 |
| | treatment | Highest temperature [° C.] | — | 400 | 400 | 400 |
| | | Retention time [hour] | — | 1 | 1 | 1 |
| | | Atmosphere | — | Atmospheric | Atmospheric | Atmospheric |
| | Formation of gate | Gate insulating film | SiO₂ | SiO₂ | SiO₂ | SiO₂ |
| | insulating film | Thickness [nm] | 100 | 100 | 100 | 100 |
| | Annealing | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | Refer to Table 2 for continuation of TFT production conditions | | | | | |
| Evaluation | Average value of A/B*⁾ | Insulating film | 1.74 | 1.65 | 1.58 | 1.61 |
| results | | Channel layer | 1.72 | 1.77 | 1.55 | 1.51 |
| | TFT characteristics | Maximum value of saturation mobility [cm²/Vs] | 30 | 50 | 30 | 35 |
| | | Optical reliability (NBTIS) ΔVth [V] | 0.8 | 0.9 | 0.4 | 0.6 |

| | | | Example 13 | Example 14 | Example 15 | Example 16 |
|---|---|---|---|---|---|---|
| Sputtering | Loaded composition ratio | In₂O₃ | 89.4 | 89.4 | 89.0 | 95.0 |
| target | [mass %] | Ga₂O₃ | 10.6 | 10.6 | 9.8 | 5.0 |
| | | Other additive elements | 0.0 | 0.0 | Al₂O₃ 1.2 | 0.0 |
| | Metal composition ratio | In | 85.0 | 85.0 | 83.2 | 92.8 |
| | [at %] | Ga | 15.0 | 15.0 | 13.5 | 7.2 |
| | | Other additive elements | 0.0 | 0.0 | Al 3.3 | 0.0 |
| TFT | Formation of channel layer | Pressure at time of film formation [Pa] | 0.5 | 0.5 | 0.5 | 0.5 |
| production | | Oxygen partial pressure at time of film formation | 0.00 | 0.05 | 0.00 | 0.00 |
| conditions | | [Pa] | | | | |
| | | Water partial pressure at time of film formation | 0.01 | 0.00 | 0.01 | 0.01 |
| | | [Pa] | | | | |
| | | Magnetic flux density [G] | 600 | 600 | 600 | 600 |
| | | Thickness [nm] | 30 | 30 | 30 | 30 |
| | Channel layer patterning | Semiconductor etching | Oxalic acid | Oxalic acid | Oxalic acid | Oxalic acid |
| | Annealing | Temperature increase pattern [° C./min] | 10 | 10 | 10 | 10 |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Surface treatment | Treatment species | SiO₂ | SiO₂ | SiO₂ | SiO₂ |
| | | Treatment method | Sputtering | Sputtering | Sputtering | Sputtering |
| | | Thickness [nm] | 10 | 10 | 10 | 10 |
| | Annealing after surface | Temperature increase pattern [° C./min] | 10 | 10 | 10 | 10 |
| | treatment | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | Formation of gate | Gate insulating film | SiO₂ | SiO₂ | SiO₂ | SiO₂ |
| | insulating film | Thickness [nm] | 100 | 100 | 100 | 100 |
| | Annealing | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | Refer to Table 2 for continuation of TFT production conditions | | | | | |
| Evaluation | Average value of A/B*⁾ | Insulating film | 1.65 | 1.65 | 1.62 | 1.5 |
| results | | Channel layer | 1.67 | 1.72 | 1.55 | 1.5 |
| | TFT characteristics | Maximum value of saturation mobility [cm²/Vs] | 38 | 39 | 35 | 42 |
| | | Optical reliability (NBTIS) ΔVth [V] | 0.5 | 0.5 | 0.1 | 0.2 |

TABLE 1-3

| | | | Comparative | Comparative | Comparative | Comparative |
|---|---|---|---|---|---|---|
| | | | Example 1 | Example 2 | Example 3 | Example 4 |
| Sputtering | Loaded composition ratio | In₂O₃ | 89.0 | 89.0 | 89.0 | 89.0 |
| target | [mass %] | Ga₂O₃ | 9.8 | 9.8 | 9.8 | 9.8 |
| | | Other additive elements | Al₂O₃ 1.2 | Al₂O₃ 1.2 | Al₂O₃ 1.2 | Al₂O₃ 1.2 |
| | Metal composition ratio | In | 83.2 | 83.2 | 83.2 | 83.2 |
| | [at %] | Ga | 13.5 | 13.5 | 13.5 | 13.5 |
| | | Other additive elements | Al 3.3 | Al 3.3 | Al 3.3 | Al 3.3 |
| TFT | Formation of channel | Pressure at time of film formation [Pa] | 0.5 | 0.5 | 0.5 | 0.5 |
| production | layer | Oxygen partial pressure at time of film formation [Pa] | 0.05 | 0.05 | 0.05 | 0.05 |
| conditions | | Water partial pressure at time of film formation [Pa] | 0.00 | 0.00 | 0.00 | 0.00 |
| | | Magnetic flux density [G] | 600 | 600 | 600 | 600 |
| | | Thickness [nm] | 30 | 30 | 30 | 30 |
| | Channel layer patterning | Semiconductor etching | Oxalic acid | Oxalic acid | Oxalic acid | Oxalic acid |
| | Annealing | Temperature increase pattern [° C./min] | 10 | 10 | 10 | 10 |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Surface treatment | Treatment species | — | SiO₂ | SiO₂ | N₂O |
| | | Treatment method | — | Sputtering | Sputtering | Plasma |
| | | | | | | oxidation |
| | | | | | | treatment |
| | | Thickness [nm] | — | 50 | 10 | No film |
| | | | | | | formation at |
| | | | | | | time of |
| | | | | | | surface |
| | | | | | | treatment |
| | Annealing after surface | Temperature increase pattern [° C./min] | — | 10 | — | 10 |
| | treatment | Highest temperature [° C.] | — | 400 | — | 400 |
| | | Retention time [hour] | — | 1 | — | 1 |
| | | Atmosphere | — | Atmospheric | — | Atmospheric |
| | Formation of gate | Gate insulating film | SiO₂ | SiO₂ | SiO₂ | SiO₂ |
| | insulating film | Thickness [nm] | 100 | 100 | 100 | 100 |
| | Annealing | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | Refer to Table 2 for continuation of TFT production conditions | | | | | |
| Evaluation | Average value of A/B*⁾ | Insulating film | 1.76 | 1.81 | 1.86 | 1.88 |
| results | | Channel layer | 1.88 | 1.73 | 1.76 | 1.68 |
| | TFT characteristics | Maximum value of saturation mobility [cm²/Vs] | 45 | 60 | 70 | 45 |
| | | Optical reliability (NBTIS) ΔVth [V] | 2.5 | 3 | 3.8 | 2.8 |

*) In“Average value of A/B, “A represents the number of oxygen atoms that exist in a state of being bonded to cation atoms, and B represents the number of the cation atoms that exist in a state of being bonded to the oxygen atoms. The cation atoms are cationic atomic species contained in the laminate structure in an amount of 1 at % or more.

TABLE 2

| | | | Examples 1 to 16 |
|---|---|---|---|
| | | | and Comparative |
| | | | Examples 1 to 4 |
| TFT | Formation of gate | Gate electrode | Mo |
| production | electrode | Thickness [nm] | 150 |
| conditions | Gate patterning | Gate electrode | PAN |
| (continued) | | etchant | |
| | | Gate insulating film | BHF |
| | | etchant | |
| | | Cleaning etchant | ITO-06N |
| | Formation of ITO | Oxygen partial | 2.0 |
| | layer | pressure at time | |
| | | of film formation | |
| | | [%] | |
| | | Thickness [nm] | 2 |
| | Low-resistance | Highest temperature | 350 |
| | annealing | [° C.] | |
| | | Retention time | 1 |
| | | [hour] | |
| | | Atmosphere | Atmospheric |
| | Formation of | Insulating film | SiO₂ |
| | interlayer | Thickness [nm] | 150 |
| | insulating film | | |
| | Formation of | Etchant | BHF |
| | contact hole in | | |
| | interlayer | | |
| | insulating film | | |
| | Formation of | Electrode | Mo |
| | electrode | | |
| | Final annealing | Highest temperature | 300 |
| | | [° C.] | |
| | | Retention time | 1 |
| | | [hour] | |
| | | Atmosphere | N₂ |

As shown in Tables 1-1 and 1-2, the TFTs of Examples 1 to 8 and 10 to 16, in which surface treatment with respect to the channel layer was performed on the channel layer by sputtering film formation or CVD film formation, annealing treatment was performed after the surface treatment, and a gate insulating film was further formed, followed by annealing treatment, each exhibited a satisfactory mobility of 30 cm²/Vs or more, and the optical reliability (NBTIS) ΔVth [V] thereof was suppressed to a low value, resulting in high reliability.

As shown in Table 1-2, the TFT of Example 9, in which N₂O plasma oxidation treatment with respect to the channel layer (surface treatment with respect to the channel layer) was performed and a gate insulating film was formed without performance of subsequent annealing treatment, exhibited a satisfactory mobility of 30 cm²/Vs or more, and the optical reliability (NBTIS) ΔVth [V] thereof was suppressed to a low value, resulting in high reliability.

### INDUSTRIAL APPLICABILITY

The crystalline oxide thin film of the present disclosure can be suitably used as a constituent member of a thin film transistor, for example, a channel layer. In addition, the thin film transistor of the present disclosure can be used in an electric circuit to be used in an electric device, an electronic device, a vehicle, or a power engine.

Some embodiments and/or Examples of the present disclosure have been described above in detail, but it is easy for a person skilled in the art to add a large number of modifications to these illustrative embodiments and/or Examples without substantially departing from the novel teachings and effects of the present disclosure. Thus, the large number of modifications are encompassed in the scope of the present disclosure.

The literatures described herein and the contents of the applications based on which the priority under the Paris Convention of the present application is claimed are incorporated herein in their entirety.

1. A laminate structure, comprising:
a crystalline oxide semiconductor film containing In as a main component; and
an insulating film laminated to form an interface with the crystalline oxide semiconductor film,
wherein the laminate structure has a region that satisfies the following formula (1) in the insulating film having a thickness extending from the interface to a distance approximately equal to a thickness of the crystalline oxide semiconductor film:
$$1.25 \leq ( average value of A / B ) \leq 1.75 \qquad ( 1 )$$
where A represents the number of oxygen atoms, and B represents the number of cation atoms that exist in a state of being bonded to the oxygen atoms, the cation atoms being cationic atomic species contained in the laminate structure in an amount of 1 at % or more.

2. The laminate structure according to claim 1, wherein the laminate structure has a region that satisfies the formula (1) in the crystalline oxide semiconductor film.

3. The laminate structure according to claim 1, wherein the insulating film is any one of an oxide film containing silicon (Si) as a main component, a nitride film containing silicon (Si) as a main component, and an oxynitride film containing silicon (Si) as a main component.

4. The laminate structure according to claim 1, wherein the insulating film is an oxide film containing silicon (Si) as a main component.

5. The laminate structure according to claim 1, wherein the crystalline oxide semiconductor film further contains Ga.

6. The laminate structure according to claim 1, wherein the crystalline oxide semiconductor film further contains one or more kinds of additive elements selected from B, Al, Si, Sc, Zn, Ge, Y, Zr, Sn, Sm, and Yb.

7. The laminate structure according to claim 1, wherein an atomic ratio of In with respect to all metal elements contained in the crystalline oxide semiconductor film ([In]/([In]+[all metal elements except In])×100) is 62 at % or more.

8. The laminate structure according to claim 5, wherein an atomic ratio of Ga with respect to all metal elements contained in the crystalline oxide semiconductor film ([Ga]/([Ga]+[all metal elements except Ga])×100) is 30 at % or less.

9. The laminate structure according to claim 6, wherein an atomic ratio of a total amount of the additive elements with respect to all metal elements contained in the crystalline oxide semiconductor film ([total amount of additive elements]/([total amount of additive elements]+[all metal elements except additive elements])×100) is 10 at % or less.

10. The laminate structure according to claim 1, wherein the crystalline oxide semiconductor film has a carrier concentration of 1×10¹⁸ cm⁻³ or less.

11. The laminate structure according to claim 1, wherein the crystalline oxide semiconductor film contains a crystal grain having a bixbyite structure.

12. A thin film transistor, comprising the laminate structure of claim 1,
wherein the thin film transistor includes:
a channel layer;
a source electrode and a drain electrode each connected to the channel layer; and
a gate electrode laminated on the channel layer through intermediation of a gate insulating film,
wherein the channel layer is the crystalline oxide semiconductor film in the laminate structure, and
wherein the gate insulating film is the insulating film in the laminate structure.

13. The thin film transistor according to claim 12, wherein the thin film transistor is a top-gate type transistor.

14. A semiconductor element, comprising the laminate structure of claim 1.

15. A diode, a thin film transistor, a MOSFET, or a MESFET, comprising the semiconductor element of claim 14.

16. An electronic circuit, comprising the diode, the thin film transistor, the MOSFET, or the MESFET of claim 15.

17. An electric device, an electronic device, a vehicle, or a power engine, comprising the electronic circuit of claim 16.
